(19) United States
(12) Patent Application Publication
(10) Pub. No.: US 2026/0047014 A1
(43) Pub. Date: Feb. 12, 2026

(54) ADHESIVE STRUCTURE AND ELECTRONIC DEVICE INCLUDING THE SAME

(71) Applicant: SAMSUNG ELECTRONICS CO., LTD., Suwon-si (KR)

(72) Inventors: Borami CHANG, Suwon-si (KR); Sangin Baek, Suwon-si (KR); Intaek Lee, Suwon-si (KR)

(73) Assignee: SAMSUNG ELECTRONICS CO., LTD., Suwon-si (KR)

(21) Appl. No.: 19/244,652

(22) Filed: Jun. 20, 2025

Related U.S. Application Data
(63) Continuation of application No. PCT/KR2025/007421, filed on May 30, 2025.

(30) Foreign Application Priority Data
Aug. 9, 2024 (KR) 10-2024-0106718
Aug. 29, 2024 (KR) 10-2024-0116792

(51) Int. Cl. H05K 5/00

(52) U.S. Cl. CPC H05K 5/0069; H05K 5/0086

(57) ABSTRACT

An electronic device may include a housing; a cover disposed over the housing; a circuit board positioned within a housing, wherein contact elements are arranged in one area of the circuit board; a conductive structure coupled along an edge of the cover, and comprising a portion electrically connected to a first contact element among the contact elements; and a conductive adhesive sheet coupled along an edge of the housing and shape corresponding to the conductive structure, the conductive adhesive sheet comprising a portion electrically connected to a second contact element among the contact elements. The conductive adhesive sheet may be configured to adhere to the conductive structure. The conductive structure and the conductive adhesive may be configured such that when a voltage is applied to the conductive structure and the conductive adhesive sheet, an adhesive force between the conductive structure and the conductive adhesive sheet decreases.

### CROSS-REFERENCE TO RELATED APPLICATIONS

This application is a continuation of International Application No. PCT/KR2025/007421 designating the United States, filed on May 30, 2025, in the Korean Intellectual Property Receiving Office, and claiming priority to Korean Patent Application Nos. 10-2024-0106718, filed on Aug. 9, 2024, and 10-2024-0116792, filed on Aug. 29, 2024, in the Korean Intellectual Property Office, the disclosures of each of which are incorporated by reference herein in their entireties.

### BACKGROUND

### 1. Field

The disclosure relate to an adhesive structure and an electronic device including the same.

### 2. Description of Related Art

Advancing information communication and semiconductor technologies accelerate the spread and use of various electronic devices. In particular, recent electronic devices are being developed to carry out communication while carried.

The term “electronic device” may mean a device performing a particular function according to its equipped program, such as a home appliance, an electronic scheduler, a portable multimedia player, a mobile communication terminal, a tablet personal computer (PC), a video/sound device, a desktop PC or laptop computer, a navigation for automobile, etc.

For example, electronic devices may output stored information as voices or images. As electronic devices are highly integrated, and high-speed, high-volume wireless communication becomes commonplace, an electronic device, such as a mobile communication terminal, is recently being equipped with various functions. For example, an electronic device comes with the integrated functionality, including an entertainment function, such as playing video games, a multimedia function, such as replaying music/videos, a communication and security function for mobile banking, and a scheduling or e-wallet function. These electronic devices have been downsized to be conveniently carried by users.

The above-described information may be provided as related art for the purpose of helping understanding of the disclosure. No claim or determination is made as to whether any of the foregoing is applicable as background art in relation to the disclosure.

### SUMMARY

According to an aspect of the disclosure, an electronic device may include: a housing; a cover disposed over the housing; a circuit board positioned within a housing, wherein contact elements are arranged in one area of the circuit board; a conductive structure coupled along an edge of the cover, and conductive structure comprising a portion electrically connected to a first contact element among the contact elements; and a conductive adhesive sheet coupled along an edge of the housing and having a shape corresponding to the conductive structure, the conductive adhesive sheet comprising a portion electrically connected to a second contact element among the contact elements. The conductive adhesive sheet may be configured to adhere to the conductive structure. The conductive structure and the conductive adhesive may be configured such that when a voltage is applied to the conductive structure and the conductive adhesive sheet, an adhesive force between the conductive structure and the conductive adhesive sheet decreases.

According to an aspect of the disclosure, an electronic device may include: a housing; a cover disposed over the housing; a conductive structure coupled along an edge of the cover; a circuit board positioned in the housing; and a conductive adhesive sheet disposed along an edge of the housing and having a shape corresponding to the conductive structure, the conductive sheet being configured to adhere to the conductive structure. A portion of the conductive structure and a portion of the conductive adhesive sheet may extend inward of the circuit board to be electrically connected to the circuit board. The conductive structure and the conductive adhesive may be configured such that when a voltage is applied to the conductive structure and the conductive adhesive sheet, an adhesive force between the conductive structure and the conductive adhesive sheet decreases.

The disclosure is not limited to the foregoing embodiments but various modifications or changes may be made thereto without departing from the spirit and scope of the disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram illustrating an electronic device in a network environment according to an embodiment of the disclosure;

FIG. 2 is a front exploded perspective view illustrating an electronic device according to an embodiment of the disclosure.

FIG. 3 is a rear perspective view illustrating an electronic device according to an embodiment of the disclosure.

FIG. 4 is a front exploded perspective view illustrating an electronic device according to an embodiment of the disclosure.

FIG. 5 is a rear exploded perspective view illustrating an electronic device according to an embodiment of the disclosure.

FIG. 6 is a view illustrating a power application state of an electronic device and a protective cover separated from a housing in relation thereto, according to an embodiment of the disclosure;

FIG. 7 is an exploded perspective view illustrating a housing of an electronic device and an adhesive structure including a protective cover, and components related thereto, according to an embodiment of the disclosure;

FIG. 8 is a perspective view illustrating an area inside an electronic device with a protective cover excluded according to an embodiment of the disclosure;

FIG. 9 is a cross-sectional view illustrating a stacked state of an adhesive structure in an area of an electronic device according to an embodiment of the disclosure;

FIG. 10 is a cross-sectional view of a portion the electronic device of FIG. 8, taken along A-A′ according to an embodiment of the disclosure;

FIG. 11 is a cross-sectional view of a portion the electronic device of FIG. 8, taken along B-B′ according to an embodiment of the disclosure;

FIG. 12 is a view illustrating a state in which a voltage is applied in the cross-sectional view of the electronic device of FIG. 10 according to an embodiment of the disclosure;

FIG. 13 is a view illustrating a state in which a voltage is applied in the cross-sectional view of the electronic device of FIG. 11 according to an embodiment of the disclosure;

FIG. 14 is a view illustrating separation of charges related to electrical delamination after a voltage is applied to an adhesive structure according to an embodiment of the disclosure;

FIG. 15 is a view illustrating a configuration related to the electrical delamination of FIG. 14 according to an embodiment of the disclosure;

FIG. 16 is a flowchart illustrating a separation process between a housing and a protective cover of an electronic device according to an embodiment of the disclosure;

FIG. 17 is a flowchart illustrating a delamination process between a housing and a protective cover of an electronic device according to an embodiment of the disclosure;

FIG. 18 is a cross-sectional view of a portion the electronic device of FIG. 8, taken along B-B′ according to an embodiment of the disclosure;

FIG. 19 is a cross-sectional view of a portion the electronic device of FIG. 8, taken along A-A′ according to an embodiment of the disclosure;

FIG. 20 is a cross-sectional view of a portion the electronic device of FIG. 8, taken along B-B′ according to an embodiment of the disclosure;

FIG. 21 is a cross-sectional view of A portion the electronic device of FIG. 8, taken along A-A′ according to an embodiment of the disclosure;

FIG. 22 is a cross-sectional view of a portion the electronic device of FIG. 8, taken along B-B′ according to an embodiment of the disclosure;

FIG. 23 is a cross-sectional view of a portion the electronic device of FIG. 8, taken along A-A′ according to an embodiment of the disclosure; and

FIG. 24 is a cross-sectional view of a portion the electronic device of FIG. 8, taken along B-B′ according to an embodiment of the disclosure.

Reference may be made to the accompanying drawings in the following description, and specific examples that may be practiced are shown as examples within the drawings. Other examples may be utilized and structural changes may be made without departing from the scope of the various examples.

### DETAILED DESCRIPTION

The electronic device according to embodiments of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

An embodiment of the disclosure and terms used therein are not intended to limit the technical features described in the disclosure to specific embodiments, and should be understood to include various modifications, equivalents, or substitutes of the embodiment. With regard to the description of the drawings, similar reference numerals may be used to refer to similar or related elements. It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to an embodiment, each component (e.g., a module or a program) of the above-described components may include a single entity or multiple entities. Some of the plurality of entities may be separately disposed in different components. According to an embodiment, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

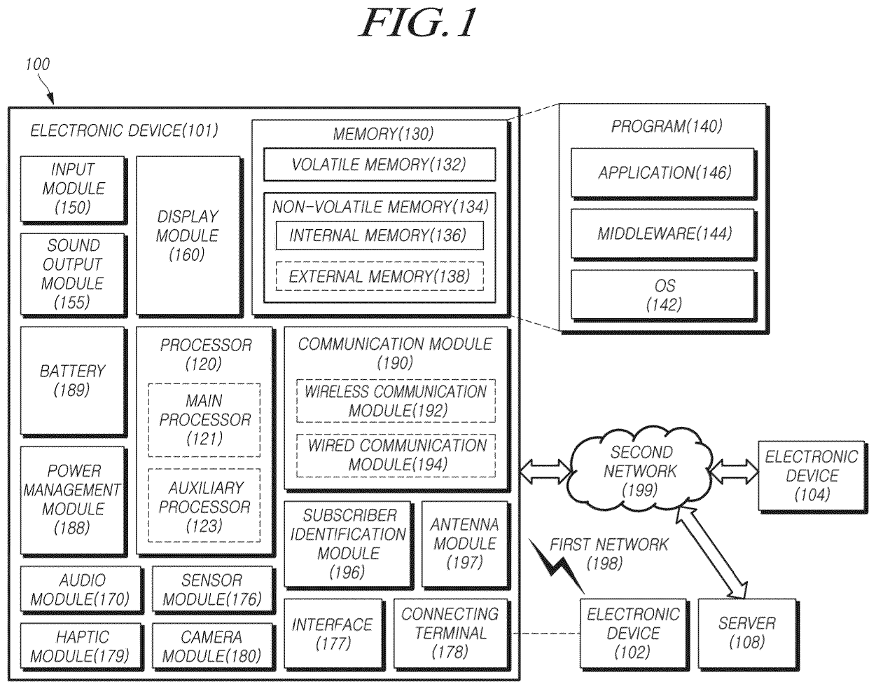

FIG. 1 is a block diagram illustrating an electronic device in a network environment according to an embodiment of the disclosure;

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. In an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. The sensor module 176 may include, e.g., a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, a SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

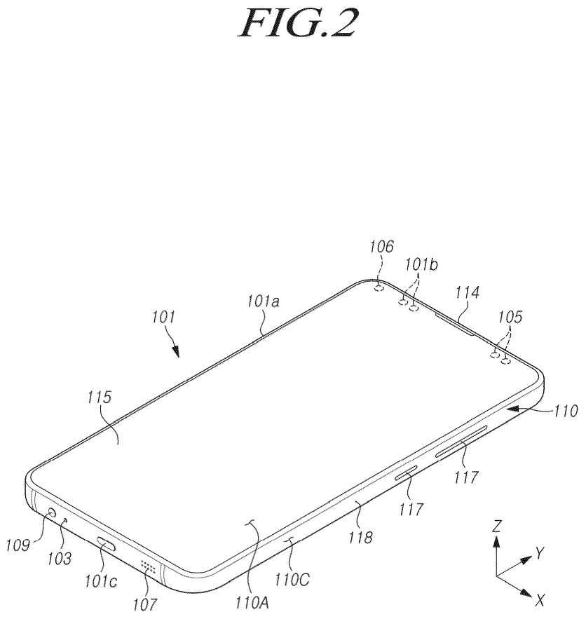

FIG. 2 is a front exploded perspective view illustrating an electronic device according to an embodiment of the disclosure.

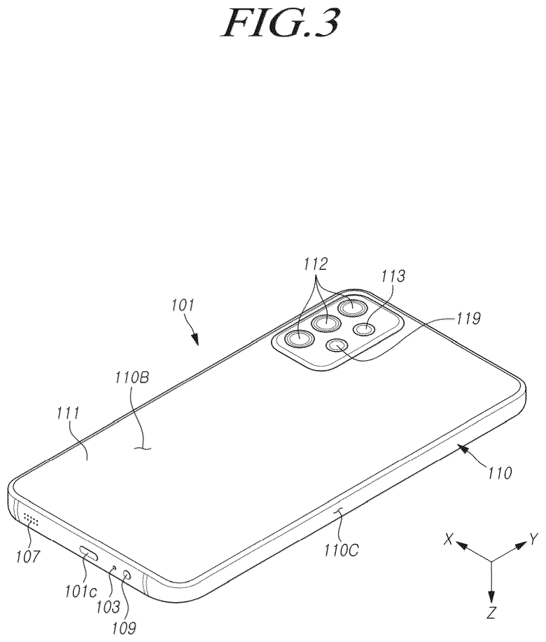

FIG. 3 is a rear perspective view illustrating an electronic device according to an embodiment of the disclosure.

The components of the electronic device 101 of FIGS. 2 and 3 may be identical in whole or part to the components of the electronic device 101 of FIG. 1.

Referring to FIGS. 2 and 3, according to an embodiment, an electronic device 101 (e.g., the electronic device 101 of FIG. 1) may include a housing 110 including a first surface (or front side) 110A, a second surface (or rear side) 110B, and a side surface (or lateral side) 110C surrounding a space between the first surface 110A and the second surface 110B. According to an embodiment (not shown), the housing 110 may denote a structure forming the first surface 110A of FIG. 2, the second surface 110B of FIG. 3, and some of the side surfaces 110C.

According to an embodiment, at least part of the first surface 110A may have a front plate 101a that is substantially transparent (e.g., a glass plate or polymer plate including various coat layers). The second surface 110B may be formed by a rear plate 111 that is substantially opaque. The rear plate 111 may be formed of, e.g., laminated or colored glass, ceramic, polymer, metal (e.g., aluminum, stainless steel (STS), or magnesium), or a combination of at least two thereof. The side surface 110C may be formed by a side structure (or a “side bezel structure”) 118 that couples to the front plate 101a and the rear plate 111 and includes a metal and/or polymer. In an embodiment, the rear plate 111 and the side structure 118 may be integrally formed together and include the same material (e.g., a metal, such as aluminum).

According to an embodiment, the front plate 101a may include area(s) that bend from at least a portion of an edge toward the rear plate 111 and extended seamlessly. For example, only one of the areas of the front plate 101a (or the rear plate 111), which bends toward the rear plate 111 (or front plate 101a) and extended, may be included in one edge of the first surface 110A. According to an embodiment, the front plate 101a or rear plate 111 may be substantially flat and, in such a case, the front plate 101a or rear plate 111 may not include a bent/extended area with bent and extended characteristics. If a bent/extended area is included in the front plate 101a or rear plate 111, the thickness of the electronic device 101 at the portion including the bent/extended area may be smaller than the thickness of the rest.

According to an embodiment, the electronic device 101 may include at least one of a display 115, an audio module (e.g., the microphone hole 103, the external speaker hole 107, and the phone receiver hole 114), a sensor module (e.g., the first sensor module 101b, the second sensor module, or the third sensor module 119), a camera module (e.g., the first camera device 105, the second camera device 112, or the flash 113), a key input device 117, a light emitting device 106, and a connector hole (e.g., the first connector hole 101c or the second connector hole 109). In an embodiment, the electronic device 101 may exclude at least one (e.g., the key input device 117 or the light emitting device 106) of the components or may add other components.

The display 115 may output a screen or be visually exposed through a significant portion of the first surface 110A (e.g., the front plate 101a), for example. In an embodiment, at least a portion of the display 115 may be visually exposed through the front plate 101a forming the first surface 110A, or through a portion of the side surface 110C. In an embodiment, the edge of the display 115 may be formed to be substantially the same in shape as an adjacent outer edge of the front plate 101a. In an embodiment (not illustrated), the interval between the outer edge of the display 115 and the outer edge of the front plate 101a may remain substantially even to give a larger area of visual exposure of the display 115.

According to an embodiment, a recess or an opening may be formed in a portion of the screen display area of the display 115, and the electronic device 101 may include at least one of an audio module (e.g., the phone receiver hole 114), a sensor module (e.g., the first sensor module 101b), a camera module (e.g., the first camera device 105), and a light emitting device 106 that are aligned with the recess or the opening. According to an embodiment, at least one of the audio module (e.g., the phone receiver hole 114), sensor module (e.g., the first sensor module 101b), camera module (e.g., the first camera device 105), fingerprint sensor, and light emitting device 106 may be disposed on the rear side (e.g., surface) of the screen display area of the display 115. According to an embodiment, the display 115 may be coupled with or disposed adjacent to a touch detection circuit, a pressure sensor capable of measuring the strength (pressure) of touches, and/or a digitizer for detecting a magnetic field-type stylus pen.

According to an embodiment, the audio modules 103, 107, and 114 may include a microphone hole 103 and speaker holes (e.g., the external speaker hole 107 and the phone receiver hole 114). A microphone for acquiring external sounds may be disposed in the microphone hole 103. In an embodiment, a plurality of microphones may be disposed to detect the direction of the sound. The speaker holes may include an external speaker hole 107 and a phone receiver hole 114. According to an embodiment, the speaker holes (e.g., the external speaker hole 107 and the phone receiver hole 114) and the microphone hole 103 may be implemented as a single hole, or speakers may be included without the speaker holes (e.g., the external speaker hole 107 and the phone receiver hole 114) (e.g., piezo speakers).

According to an embodiment, the sensor module may generate an electrical signal or data value corresponding to an internal operating state or external environmental state of the electronic device 101. The sensor modules may include a first sensor module 101b (e.g., a proximity sensor) and/or a second sensor module (e.g., a fingerprint sensor) disposed on the first surface 110A of the housing 110 and/or a third sensor module 119 disposed on the second surface 110B of the housing 110. The second sensor module (e.g., a fingerprint sensor) may be disposed on the second surface 110B or side surface 110C as well as the first surface 110A (e.g., the display 115) of the housing 110. The electronic device 101 may further include, e.g., at least one of a gesture sensor, a gyro sensor, an atmospheric pressure sensor, a magnetic sensor, an acceleration sensor, a grip sensor, a color sensor, an IR sensor, a biometric sensor, a temperature sensor, a humidity sensor, or an illuminance sensor.

According to an embodiment, the camera modules may include a first camera device 105 disposed on the first surface 110A of the electronic device 101, and a second camera device 112 and/or a flash 113 disposed on the second surface 110B. The camera devices (e.g., the first camera device 105 and the second camera device 112) may include one or more lenses, an image sensor, and/or an image signal processor. The flash 113 may include, e.g., a light emitting diode or a xenon lamp. In an embodiment, one or more lenses (an IR camera, a wide-angle lens, and a telephoto lens) and image sensors may be disposed on one side (e.g., surface) of the electronic device 101. In an embodiment, flash 113 may emit IR light. The IR light emitted by the flash 113 and reflected by the subject may be received through the third sensor module 119. The electronic device 101 or the processor (e.g., the processor 120 of FIG. 1) of the electronic device 101 may detect depth information about the subject based on the time point when the IR light is received from the third sensor module 119.

According to an embodiment, the key input device 117 may be disposed on the side surface 110C of the housing 110. In an embodiment, the electronic device 101 may exclude all or some of the above-mentioned key input devices 117 and the excluded key input devices 117 may be implemented in other forms, e.g., as soft keys, on the display 115. In an embodiment, the key input device may include the sensor module disposed on the second surface 110B of the housing 110.

According to an embodiment, the light emitting device 106 may be disposed on the first surface 110A of the housing 110, for example. The light emitting device 106 may provide, e.g., information about the state of the electronic device 101 in the form of light. In an embodiment, the light emitting device 106 may provide a light source that interacts with, e.g., the camera module (e.g., the first camera device 105). The light emitting device 106 may include, e.g., a light emitting diode (LED), an IR LED, or a xenon lamp.

According to an embodiment, the connector holes (e.g., the first connector hole 101c or the second connector hole 109) may include, e.g., a first connector hole 101c for receiving a connector (e.g., a USB connector) for transmitting/receiving power and/or data to/from an external electronic device (e.g., the electronic device 1002 of FIG. 1) and/or a second connector hole 109 (e.g., an earphone jack) for receiving a connector for transmitting/receiving audio signals to/from the external electronic device.

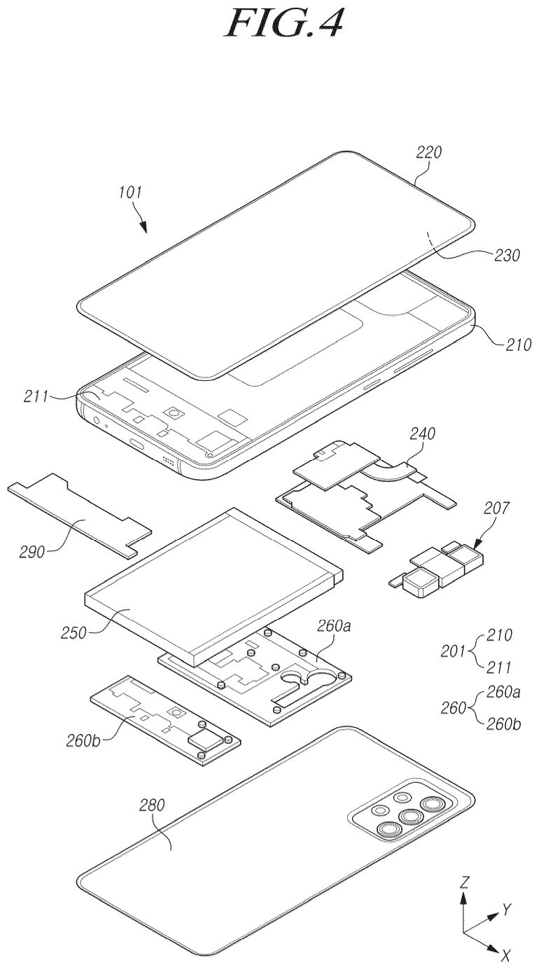

FIG. 4 is a front exploded perspective view illustrating an electronic device according to an embodiment of the disclosure.

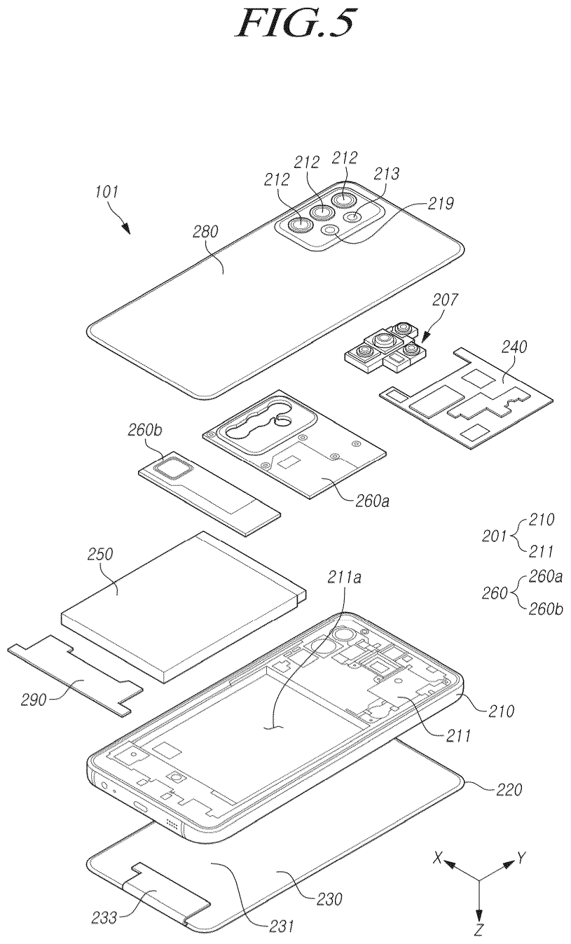

FIG. 5 is a rear exploded perspective view illustrating an electronic device according to an embodiment of the disclosure.

The components of the electronic device 101 of FIGS. 4 and 5 may be identical in whole or part to the components of the electronic device 101 of FIGS. 1 to 3.

Referring to FIGS. 4 and 5, an electronic device 101 (e.g., the electronic device 101 of FIG. 1, 2, or 3) may include a side structure 210, a first supporting member 211 (e.g., a bracket), a front plate 220 (e.g., the front plate 101a of FIG. 2), a display 230 (e.g., the display 115 of FIGS. 2 and 3), a PCB (or a board assembly) 240, a battery 250, a second supporting member 260 (e.g., a rear case), an antenna, a camera assembly 207, and a rear plate 280 (e.g., the rear plate 111 of FIG. 3).

According to an embodiment, the electronic device 101 may exclude at least one (e.g., the first supporting member 211 or the second supporting member 260) of the components or may add other components. At least one of the components of the electronic device 101 may be the same or similar to at least one of the components of the electronic device 101 of FIG. 2 or 3 and no duplicate description is made below.

According to an embodiment, the first supporting member 211 may be disposed inside the electronic device 101 to be connected with the side structure 210 or integrated with the side structure 210. The first supporting member 211 may be formed of, e.g., a metallic material and/or non-metallic material (e.g., polymer). When at least partially formed of a metallic material, a portion of the side structure 210 or the first supporting member 211 may function as an antenna. The display 230 may be joined onto one side (e.g., surface) of the first supporting member 211, and the PCB 240 may be joined onto the opposite side (e.g., surface) of the first supporting member 232. A processor (e.g., the processor 120 of FIG. 1), memory (e.g., the memory 130 of FIG. 1), and/or an interface (e.g., the interface 177 of FIG. 1) may be mounted on the PCB 240. The processor may include one or more of, e.g., a central processing unit, an application processor, a graphic processing device, an image signal processing, a sensor hub processor, or a communication processor.

According to an embodiment, the first supporting member 211 and the side structure 210 may be collectively referred to as a front case or a housing 201. According to an embodiment, the housing 201 may be generally understood as a structure for receiving, protecting, or disposing the printed circuit board 240 or the battery 250. In an embodiment, the housing 201 may be understood as including a structure that the user may visually or tactfully recognize from the exterior of the electronic device 101, e.g., the side structure 210, the front plate 220, and/or the rear plate 280. In an embodiment, the ‘front or rear surface (or front or rear side) of the housing 201’ may mean the first surface (or front side) 110A of FIG. 2 or the second surface (or rear side) 110B of FIG. 3. In an embodiment, the first supporting member 211 may be disposed between the front plate 220 (e.g., the first surface 110A of FIG. 2) and the rear plate 280 (e.g., the second surface 110B of FIG. 3) and may function as a structure for placing an electrical/electronic component, such as the PCB 240 or the camera assembly 207.

According to an embodiment, the display 230 may include a display panel 231 and a flexible PCB 233 extending from the display panel 231. It may be understood that the flexible PCB 233 is, e.g., electrically connected to the display panel 231 while at least partially disposed on the rear side (e.g., surface) of the display panel 231. In an embodiment, reference number ‘231’ may be understood as a protective sheet disposed on the rear side (e.g., surface) of the display panel. For example, the protective sheet may be understood as a portion of the display panel 231 unless otherwise designated in the detailed description below. In an embodiment, the protective sheet may function as a cushioning structure that absorbs external force (e.g., a low-density elastic material, such as a sponge) or an electromagnetic shielding structure (e.g., a copper sheet (CU sheet)). According to an embodiment, the display 230 may be disposed on the inner side (e.g., surface) of the front plate 220 and, by including a light emitting layer, output a screen through at least a portion of the front plate 220 or the first surface 110A of FIG. 2. As mentioned above, the display 230 may output substantially the entire area of the front plate 220 or the first surface 110A of FIG. 2.

According to an embodiment, the memory may include, e.g., a volatile or non-volatile memory.

According to an embodiment, the interface may include, e.g., a high definition multimedia interface (HDMI), a universal serial bus (USB) interface, a secure digital (SD) card interface, and/or an audio interface. The interface may electrically or physically connect, e.g., the electronic device 101 with an external electronic device and may include a USB connector, an SD card/multimedia card (MMC) connector, or an audio connector.

According to an embodiment, the second supporting member 260 may include, e.g., an upper supporting member 260a and a lower supporting member 260b. In an embodiment, the upper supporting member 260a, together with a portion of the first supporting member 211, may be disposed to surround the PCB 240. A circuit device (e.g., a processor, a communication module, or memory) implemented in the form of an integrated circuit chip or various electrical/electronic components may be disposed on the PCB 240. According to an embodiment, the PCB 240 may receive an electromagnetic shielding environment from the upper supporting member 260a. In an embodiment, the lower supporting member 260b may be utilized as a structure in which electrical/electronic components, such as a speaker module and an interface (e.g., a USB connector, an SD card/MMC connector, or an audio connector) may be disposed. In an embodiment, electrical/electronic components, such as a speaker module and an interface (e.g., a USB connector, an SD card/MMC connector, or an audio connector) may be disposed on an additional PCB. In this case, the lower supporting member 260b, together with the other part of the first supporting member 211, may be disposed to surround the additional PCB. A speaker module or interface disposed on an additional PCB or lower supporting member 260b may be disposed corresponding to the connector hole (e.g., the first connector hole 101c or the second connector hole 109) or the audio module (e.g., the microphone hole 103 or the speaker hole (e.g., the external speaker hole 107 or the phone receiver hole 114)) of FIG. 2.

According to an embodiment, the battery 250 may be a device for supplying power to at least one component of the electronic device 101. The battery 189 may include, e.g., a non-rechargeable primary cell, a rechargeable secondary cell, or a fuel cell. At least a portion of the battery 250 may be disposed on substantially the same plane as the PCB 240. The battery 250 may be integrally or detachably disposed inside the electronic device 101.

According to an embodiment, the electronic device 101 may further include a separate sub circuit board 290 spaced apart from the PCB 240 in the first supporting member 211. The sub circuit board 290 may be electrically connected with the PCB 240 through a connecting member such as a connecting flexible board or a cable. The sub circuit board 290 may be electrically connected with electrical components disposed in an end area of the electronic device 101, such as the battery 289 or a speaker, a USB connector, an antenna connector, and/or a sim socket, and may transfer (e.g., transmit) signals and power.

The antenna may include a conductor pattern implemented on the side (e.g., surface) of the second supporting member 260 through, e.g., laser direct structuring. In an embodiment, the antenna may include a printed circuit pattern formed on the side (e.g., surface) of the thin film. The thin film-type antenna may be disposed between the rear plate 280 and the battery 250. The antenna may include, e.g., a near-field communication antenna, a wireless charging antenna, and/or a magnetic secure transmission antenna. The antenna may perform short-range communication with, e.g., an external device or may wirelessly transmit or receive power necessary for charging. In an embodiment of the disclosure, another antenna structure may be formed by a portion or combination of the side structure 210 and/or the first supporting member 211.

According to an embodiment, the camera assembly 207 may include at least one camera module. Inside the electronic device 101, the camera assembly 207 may receive at least a portion of the light incident through the optical hole or the camera windows 212, 213, and 219. In an embodiment, the camera assembly 207 may be disposed on the first supporting member 211 in a position adjacent to the PCB 240. In an embodiment, the camera module(s) of the camera assembly 207 may be generally aligned with either one of the camera windows 212, 213, and 219 and be a least partially surrounded by the second supporting member 260 (e.g., the upper supporting member 260a).

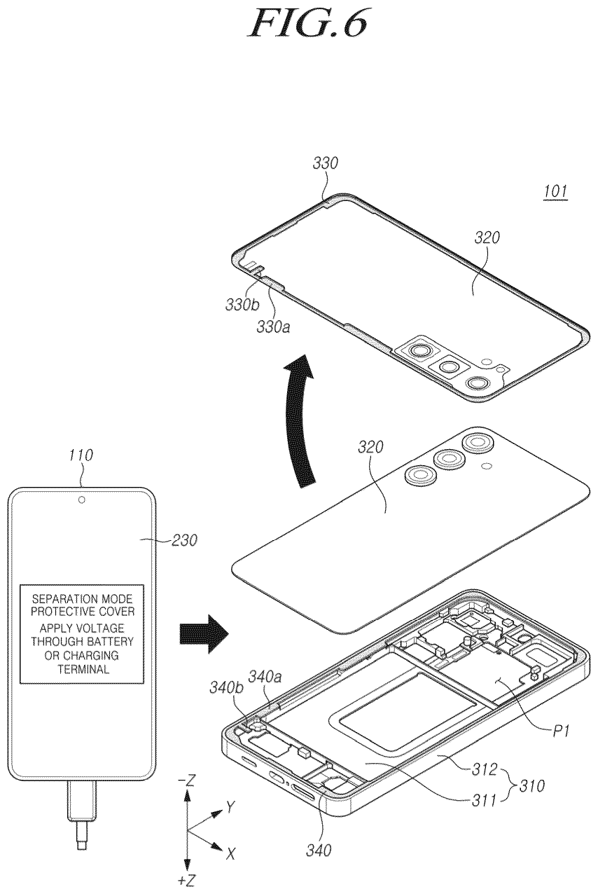

FIG. 6 is a view illustrating a power application state of an electronic device and a protective cover separated from a housing in relation thereto, according to an embodiment of the disclosure.

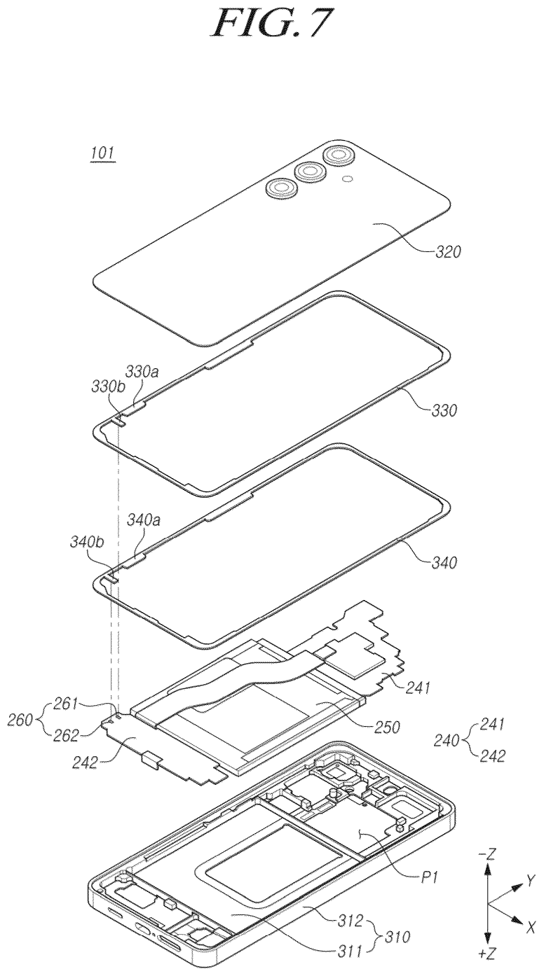

FIG. 7 is an exploded perspective view illustrating a housing of an electronic device and an adhesive structure including a protective cover, and components related thereto, according to an embodiment of the disclosure.

Referring to FIGS. 6 and 7, the electronic device 101 may include at least one of a housing 310, a protective cover 320, a circuit board 240, a battery 250, a conductive structure 330, and/or a conductive adhesive sheet 340. The housing 310, the protective cover 320, the conductive structure 330, and the conductive adhesive sheet 340 of the electronic device 101 may provide an adhesive structure.

The configuration of the electronic device 101 of FIGS. 6 and 7 may be identical in whole or part to the configuration of the electronic device 101 of FIGS. 1 to 5. The configuration of the housing 310 and the protective cover 320 of FIGS. 6 and 7 may be identical in whole or part to the configuration of the housing 201, the front plate 220 and rear plate 280 of FIGS. 4 and 5.

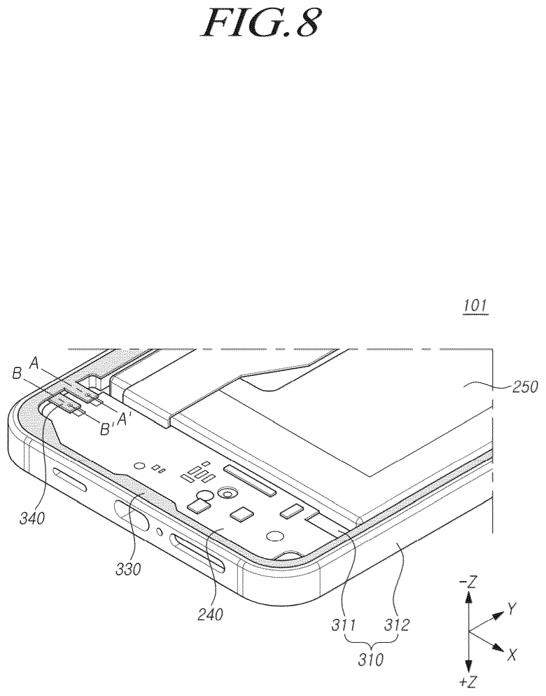

The embodiments of FIGS. 6 and 7 may be selectively combined with the embodiments of FIGS. 1 to 5 and the embodiments of FIGS. 8 to 24.

According to an embodiment, the housing 310 may form the overall outer appearance of the electronic device 101. The housing 110 of FIGS. 2 and 3 and/or the housing 201 of FIGS. 4 and 5 may be applied to the housing 310. According to an embodiment, the protective cover (or cover) 320 may be the front plate 101a or the rear plate 111 of FIGS. 2 and 3. An example in which the protective cover 320 is the rear plate is described below.

According to an embodiment, with respect to the electronic device 101, the direction in which the display (e.g., the display 230 of FIGS. 4 and 5) faces (e.g., opposes) may be defined as a front direction or a first direction (e.g., +Z-axis direction), and the direction in which the protective cover 320 faces (e.g., opposes) may be defined as a rear direction or a second direction (e.g., −Z-axis direction).

According to an embodiment, the housing 310 may include a support plate (e.g., the first supporting member 211 (e.g., a bracket) of FIGS. 4 and 5) providing the space where the electronic components are disposed and a side wall 312 (e.g., the side structure 210 of FIGS. 4 and 5) disposed in the front direction (e.g., +Z-axis direction) and/or rear direction (e.g., −Z-axis direction) along an edge of the support plate 311. The disposed space of the support plate 301 may include a front space which is open in the front direction (e.g., +Z-axis direction) and a rear space P1 which is open in the rear direction (e.g., −Z-axis direction). For example, an electronic component such as the display 230 may be disposed in the front space, and an electronic component such as the battery 250, the circuit board 240, a camera, or a sensor may be disposed in the rear space P1.

According to an embodiment, the protective cover 320 may form a structure for protecting electronic components received inside the electronic device 101. For example, the protective cover 320 may be at least one of glass, plastic (e.g., polycarbonate, acrylic, or polyurethane (e.g., thermoplastic polyurethane) or polyethylene terephthalate), or ceramic.

According to an embodiment, the circuit board 240 may be positioned in the housing 310. For example, the circuit board 240 may be disposed in the rear space P1 of the support plate 311. According to an embodiment, at least one of a processor (e.g., the processor 120 of FIG. 1), a memory (e.g., the memory 130 of FIG. 1), and/or an interface (e.g., the interface 177 of FIG. 1) may be mounted on the circuit board 240.

According to an embodiment, the circuit board 240 may have a contact element 260 mounted thereon to be electrically connected to the conductive structure 330 and/or the conductive adhesive sheet 340. The contact element 260 may be disposed in an area facing the rear side (e.g., surface) (e.g., facing the −Z-axis direction) of circuit board 240. The contact element 260 may include a first contact element 261 electrically connectable to the conductive structure 330, and a second contact element 262 electrically connectable to the conductive adhesive sheet 340. The first contact element 261 and/or the second contact element 262 may be disposed along one edge of the circuit board 240. The first contact element 261 and the second contact element 262 may be disposed in parallel and may be shaped to at least partially protrude in the rear direction (e.g., −Z-axis direction) from the circuit board 240.

According to an embodiment, the contact element 260 may include a conductive material and may provide an electrical connection between the conductive structure 330 and/or the conductive adhesive sheet 340 connected to the contact element 260 and the circuit board 240. According to an embodiment, the contact element 260 may be referred to as at least one of a grounding element, a conductive element, a current-carrying element, a C-clip, a pogo-pin, a conductive sponge or a connector, and the term “element” may be interchangeably used with at least one of a member, a part, a portion, a clip or a component.

According to an embodiment, an electrical connection from the circuit board 240 to the protective cover 320 may be provided through at least one conductive member disposed between the protective cover 320 and the conductive adhesive sheet 340. For example, at least one conductive member may serve as a bridge connecting the protective cover 320 and the contact element 260 disposed on the circuit board 240. At least one conductive member may be at least one of the antenna rear (e.g., the second supporting member 260 of FIGS. 4 and 5) and/or the conductive sponge.

According to an embodiment, the circuit board 240 may include a main circuit board 241 (e.g., a first circuit board) and a sub circuit board 242 (e.g., a second circuit board). The main circuit board 241 and the sub circuit board 242 may be disposed with the battery 250 interposed therebetween. For example, the sub circuit board 242 may be electrically connected with the main circuit board 241 through a connecting member such as a connecting flexible board or a cable. The sub circuit board 290 may be electrically connected with electrical components disposed in an end area of the electronic device 101, such as the battery 250 or a speaker, a USB connector, an antenna connector, and/or a sim socket, and may transfer (e.g., transmit) signals and power.

According to an embodiment, the battery 250 may be positioned within the housing 310. For example, the battery 250 may be disposed in the rear space P1 of the support plate 311. According to an embodiment, the battery 250 is a device for supplying power to at least one component of the electronic device 101, and a PMIC may be positioned on one side of the battery 250, as an integrated circuit for power management.

According to an embodiment, the adhesive structure of the electronic device 101 may be designed to separate the protective cover 320 from the housing 310 using the electrical delamination characteristics (or electrically induced delamination characteristics, electrical release characteristics) of the conductive structure 330 and/or the conductive adhesive sheet 340. The electrical delamination characteristic may be performed through a process of applying a voltage to the circuit board 240 and separating charges of the conductive adhesive sheet 340. According to an embodiment, the application of the voltage may be formed to occur through an external power source or the circuit board 240 electrically connected to the external power source. For example, the application of voltage may occur by the circuit board 240 electrically connected to the external power source through an external power cable (for example, a terminal adapter). For example, the application of voltage may occur by the circuit board 240 electrically connected to the battery 250 and/or the PMIC. For example, the display 230 of the electronic device 101 may display a disassembly repair mode indication of the protective cover 320 or may display whether a voltage is applied through a charging terminal or a battery and transmit it to the user.

According to an embodiment, the conductive structure 330 may be disposed along the edge of the protective cover 320 and/or the housing 310 and may be electrically connected to a first contact element 261 among contact elements 260 disposed on the circuit board 240.

According to an embodiment, the conductive structure 330 may be disposed between the protective cover 320 and the housing 310. According to an embodiment, the conductive structure 330 may be disposed between the protective cover 320 and the conductive adhesive sheet 340. The conductive structure 330 may be provided in a shape corresponding to the conductive adhesive sheet 340. For example, the conductive structure 330 may have a closed loop shape disposed along the edge of the protective cover 320.

According to an embodiment, the conductive structure 330 may be coupled along the edge of the protective cover 320. For example, the conductive structure 330 may be formed by performing at least one of depositing, printing, transferring, or lamination on a conductive material in one area of the protective cover 320. For example, the conductive structure 330 may couple an adhesive material such as an adhesive film to one area of the protective cover 320.

According to an embodiment, the conductive structure 330 may be referred to as at least one of a current-carrying structure or an electrical structure, and the term “electrical structure” may be interchangeably used with at least one of an element, a member, a part, a portion, or a component.

According to an embodiment, the conductive structure 330 may include a first connection portion 330a disposed along the edge of the protective cover 320, and a first extension portion 330b extending from one side of the first connection portion 330a to the first contact element 261. The first extension portion 330b is a portion for being electrically connected to the first contact element 261, and may extend to contact the first contact element 261 disposed on the circuit board 240.

According to an embodiment, the conductive adhesive sheet 340 may be disposed along the edge of the protective cover 320 and/or the housing 310 and may be electrically connected to the second contact element 262 among the contact elements 260 disposed on the circuit board 240.

According to an embodiment, the conductive adhesive sheet 340 may be disposed between the housing 310 and the protective cover 320. According to an embodiment, the conductive adhesive sheet 340 may be disposed between the housing 310 and the conductive structure 330. The conductive adhesive sheet 340 may be provided in a shape corresponding to the conductive structure 330. For example, the conductive adhesive sheet 340 may have a closed loop shape disposed along the edge of the housing 310.

According to an embodiment, the conductive adhesive sheet 340 may be coupled along the edge of the housing 310. For example, the conductive adhesive sheet 340 may include a second connection portion 340a disposed to overlap the side wall 312 along the side wall 312 of the housing 310, and a second extension portion 340b extending from the second connection portion 340a to the inside of the circuit board 240. For example, the conductive adhesive sheet 340 is a double-sided adhesive material, which is disposed along the side wall 312 of the housing 310 and may couple (e.g., connect or attach) the protective cover 320 coupled with the conductive structure 330 and the housing 310. The conductive adhesive sheet 340 may have a structure in which a plurality of layers are stacked, such as a material layer having electrical delamination characteristics and a material layer having adhesive capability.

According to an embodiment, the conductive adhesive sheet 340 may be referred to as at least one of an electrical delamination sheet/electrical peel-off sheet, a current-carrying adhesive sheet, or an electrical adhesive sheet. The term “adhesive” may be interchangeably used with at least one of sticky, glue, paste member, or waterproof. The term “sheet” may be interchangeably used with at least one of a tape, a film, an element, a member, a part, a portion, and a component.

According to an embodiment, the conductive adhesive sheet 340 may include a second connection portion 340a adhered to the side wall 312 along the side wall 312 of the housing 310, and a second extension portion 340b extending from the second connection portion 340a to the inside of the circuit board 240. The second extension portion 340b is a portion (e.g., section or specific area) for being electrically connected to the second contact element 262 and may extend to contact the second contact element 262 disposed on the circuit board 240.

The conductive structure 330 and the conductive adhesive sheet 340 of FIGS. 6 and 7 are disclosed in a structure in which they are disposed along all the edges of the protective cover 320 and/or the housing 700, but without limitations thereto and may be design-changed into various shapes, such as an open loop with an open side.

FIG. 8 is a perspective view illustrating an area inside an electronic device with a protective cover excluded according to an embodiment of the disclosure.

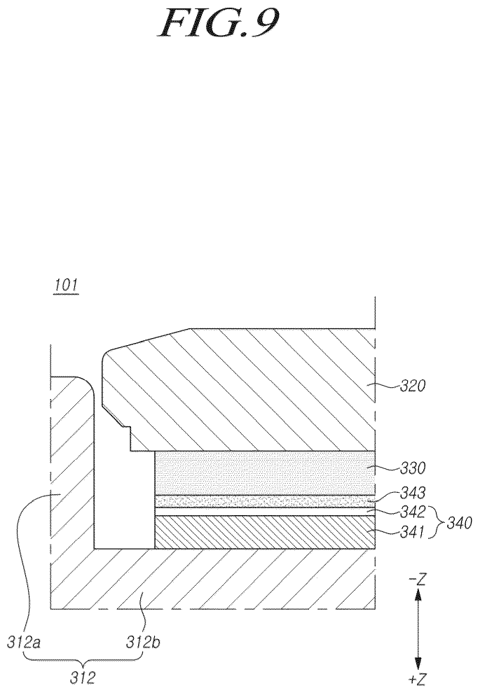

FIG. 9 is a cross-sectional view illustrating a stacked state of an adhesive structure in an area of an electronic device according to an embodiment of the disclosure.

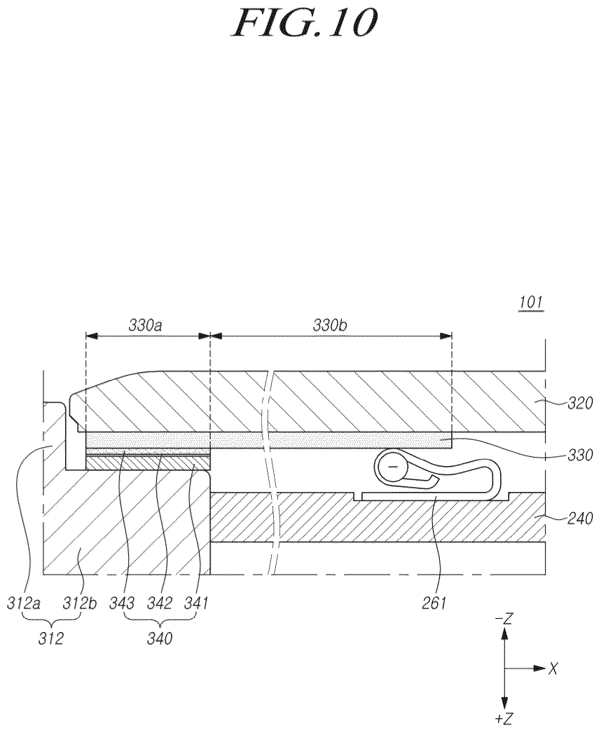

FIG. 10 is a cross-sectional view of a portion the electronic device of FIG. 8, taken along A-A′ according to an embodiment of the disclosure.

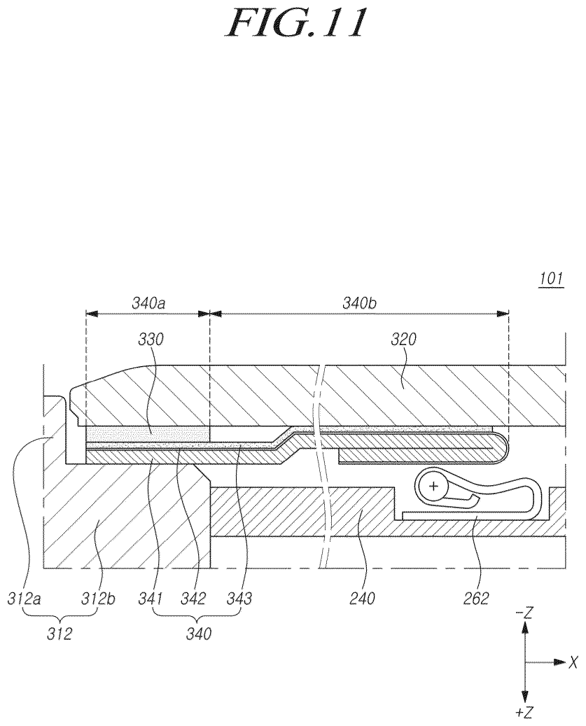

FIG. 11 is a cross-sectional view of a portion the electronic device of FIG. 8, taken along B-B′ according to an embodiment of the disclosure.

The configuration of the electronic device 101 of FIGS. 8 to 11 may be identical in whole or part to the configuration of the electronic device 101 of FIGS. 1 to 7.

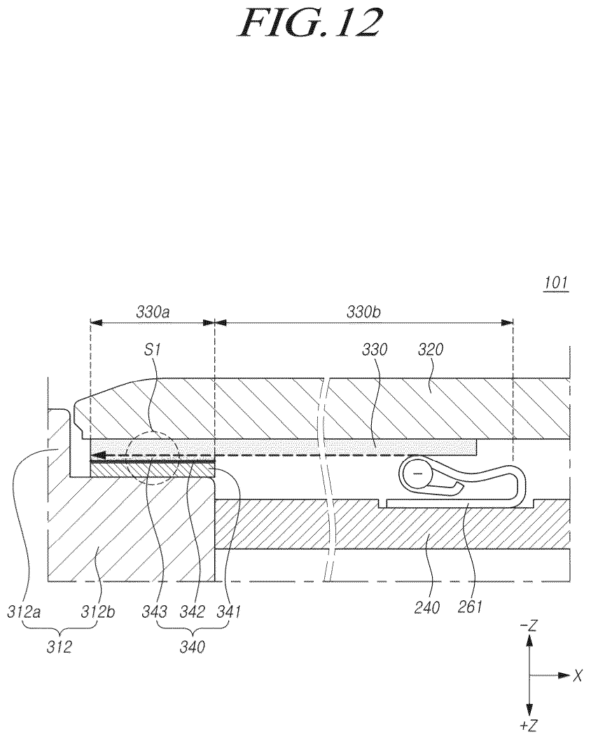

The embodiments of FIGS. 8 to 11 may be selectively combined with the embodiments of FIGS. 1 to 7 and the embodiments of FIGS. 12 to 24.

According to an embodiment, the electronic device 101 may include at least one of a housing 310, a protective cover 320, a circuit board 240, a battery 250, a conductive structure 330, and/or a conductive adhesive sheet 340.

According to an embodiment, the adhesive structure may couple the housing 310 and the protective cover 320 with a strong adhesive force. According to an embodiment, when a voltage is applied to the electronic device 101 for disassembly (e.g., a protective cover separation mode) of the electronic device 101, the adhesive force of the adhesive structure is weakened, and thus the protective cover 320 may be easily separated from the housing 310.

According to an embodiment, in the adhesive structure, a conductive adhesive sheet 340 including an adhesive component may be disposed between the housing 310 and the protective cover 320 to strengthen adhesive force. In the adhesive structure, in order to weaken adhesive force, a conductive adhesive sheet 340 including detachable charges and a conductive structure 330 forming a movement path of the charges may be stacked for electrical delamination characteristics.

According to an embodiment, the side wall 312 of the housing 310 may include a first side wall portion 312a forming an outer side (e.g., surface) of the electronic device 101 and a second side wall portion 312b extending from the first side wall portion 312a to the inside of the electronic device 101. The second side wall portion 312b may be formed to surround the edge of the support plate 311 of the housing 310, and the rear side (e.g., surface) (e.g., the surface facing in the −Z axis) may provide one side (e.g., surface) where the conductive adhesive sheet 340 adheres to the housing 310. The first side wall portion 312a and the second side wall portion 312b may have a stepped (e.g., stepwise) shape.

According to an embodiment, the adhesive structure may be a structure in which the conductive adhesive sheet 340, the conductive structure 330, and the protective cover 320 are sequentially stacked on the second side wall portion 312b of the housing 310. The first side wall portion 312a of the housing 310 may be formed to surround the lateral sides (e.g., surfaces) of the conductive adhesive sheet 340, the conductive structure 330, and the protective cover 320.

According to an embodiment, the conductive adhesive sheet 340 may include an adhesive substrate layer 341, a conductive layer 342, and an electrolyte layer 343. The adhesive substrate layer 341, the conductive layer 342, and the electrolyte layer 343 may have generally (e.g., overall) closed loop shapes corresponding to each other. The adhesive substrate layer 341, the conductive layer 342, and/or the electrolyte layer 343 may each include an extension portion (e.g., the first extension portion 330b) protruding toward the circuit board 240 (e.g., in the X-axis direction) to be connected to the contact element 260.

According to an embodiment, the adhesive substrate layer 341 of the conductive adhesive sheet 340 may be disposed between the housing 310 (e.g., the second side wall portion 312b) and the conductive layer 342. The adhesive substrate layer 341 may provide a support layer function for supporting the conductive adhesive sheet 340 as a whole (e.g., generally). The adhesive substrate layer 341 may provide an adhesive function for adhering (e.g., attaching or bonding) the conductive adhesive sheet 340 to the housing 310 and the conductive layer 342, e.g., a function of a pressure-sensitive adhesive. For example, the adhesive substrate layer 341 may be a double-sided adhesive layer and remain in a state in which one side (e.g., surface) thereof adhering to the second side wall portion 312b of the housing 310 and the other side (e.g., surface) adhering to the conductive layer 342. The adhesive substrate layer 341 remains coupled to the housing 310 and the conductive layer 342, and even if a voltage is applied to the conductive adhesive sheet 340 to separate the housing 310 and the protective cover 320, the adhesive substrate layer 341 may continuously maintain the coupled state of the housing 310 and the conductive layer 342. The adhesive substrate layer 341 may have a larger thickness compared to other layers (e.g., the conductive layer 342 and/or the electrolyte layer 343) of the conductive adhesive sheet 340.

According to an embodiment, the conductive layer 342 of the conductive adhesive sheet 340 may be disposed between the adhesive substrate layer 341 and the electrolyte layer 343. The conductive layer 342 is a layer for moving charges constituting the electrolyte layer 343 and may provide a conducting function such as metal. For example, if a voltage is applied to the conductive adhesive sheet 340, the conductive layer 342 has either a (−) pole or a (+) pole, and some of the charges of the electrolyte layer 343 may move toward the conductive layer 342. Due to the adhesive property of the adhesive substrate layer 341, the conductive layer 342 may maintain the state of adhering to the adhesive substrate layer 341. The conductive layer 342 may have a smaller thickness compared to other layers (e.g., adhesive substrate layer 341, and/or electrolyte layer 343) of the conductive adhesive sheet 340

According to an embodiment, the electrolyte layer 343 of the conductive adhesive sheet 340 may be disposed between the conductive layer 342 and the protective cover 320. According to an embodiment, the electrolyte layer 343 of the conductive adhesive sheet 340 may be disposed between the conductive layer 342 and the conductive structure 330.

According to an embodiment, the electrolyte layer 343 may provide a function of providing electrical delamination characteristics by including an electrolyte, and an adhesive function for adhering the conductive adhesive sheet 340 to the conductive layer 342 and the conductive structure 330 (or the protective cover 320), e.g., a function of a pressure-sensitive adhesive.

According to an embodiment, the electrolyte layer 343 may include a material that is dissolved in a solvent, is dissociated into ions, and has electrical conductivity, and may have a state in which (+) charges and (−) charges are mixed and distributed. The electrolyte layer 343 may be in a solid electrolyte or gel electrolyte state. If a voltage is applied to the conductive adhesive sheet 340 to separate the housing 310 and the protective cover 320, the electrolyte layer 343 may separate the (+) charges and the (−) charges so that the conductive adhesive sheet 340 and the conductive structure 330 may be easily separated.

According to an embodiment, the electrolyte layer 343 is a double-sided adhesive layer, and may maintain a state in which one side of which adheres to the conductive layer 342, and the other side adheres to the conductive structure 330. The electrolyte layer 343 may provide a property (e.g., an electrical delamination characteristic) in which the adhesive force is changed by applying a voltage.

According to an embodiment, the conductive structure 330 may be disposed between the protective cover 320 and the electrolyte layer 343 of the conductive adhesive sheet 340. The conductive structure 330 is a layer for moving charges constituting the electrolyte layer 343 and may provide a conducting function such as metal. For example, if a voltage is applied to the conductive structure 330, the conductive structure 330 has either a (−) pole or a (+) pole, and some of the charges of the electrolyte layer 343 may move toward the conductive structure 330. The conductive structure 330 maintains a state of being strongly coupled to the protective cover 320, thereby providing one side (e.g., surface) that is separated from the conductive adhesive sheet 340 if the housing 310 and the protective cover 320 are separated.

According to an embodiment, the conductive adhesive sheet 340 and the conductive structure 330 may include portions extending toward the circuit board 240 during voltage application. The conductive layer 432 of the conductive adhesive sheet 340 and the conductive structure 330 may have polarity when a voltage is applied. For example, the conductive structure 330 may include a first connection portion 330a disposed along the edge of the protective cover 320 and a first extension portion 330b extending from one side of the first connection portion 330a to the first contact element 261. For example, the conductive adhesive sheet 340 may include a second connection portion 340a disposed along the edge of the side wall of the housing 310 and a second extension portion 340b extending from one side of the second connection portion 340a to the second contact element 262.

According to an embodiment, the second extension portion 340b of the conductive adhesive sheet 340 and the first extension portion 330b of the conductive structure 330 may have shapes corresponding to each other, and may be disposed in parallel. According to an embodiment, since the conductive structure 330 is a structure stacked on the conductive adhesive sheet 340, a separation distance between the first extension portion 330b and the circuit board 240 may be larger (e.g., greater) than a separation distance between the second extension portion 340b and the circuit board 240. However, the shape of the first extension portion 330b and the shape of the second extension portion 340b and/or the separation distances from the circuit board 240 may be variously design-changed depending on the arrangement and shape of the first contact element 261 and the second contact element 262. According to an embodiment, the second extension portion 340b of the conductive adhesive sheet 340 and the first extension portion 330b of the conductive structure 330 may be disposed not to overlap when viewed from the protective cover 320 (e.g., +Z-axis direction).

According to an embodiment, one end of the second extension portion 340b of the conductive adhesive sheet 340 may be disposed to face (e.g., oppose) the second contact element 262 disposed on the circuit board 240. When a voltage is applied through the circuit board 240, the conductive layer 342 and the second contact element 262 may substantially contact each other for electrical connection between the conductive layer 342 of the conductive adhesive sheet 340 and the second contact element 262.

According to an embodiment, in the second extension portion 340b of the conductive adhesive sheet 340, the lengths of the conductive layer 342 and the adhesive substrate layer 341 may be longer (e.g., greater) than the length of the electrolyte layer 343. The conductive adhesive sheet 340 may have the conductive layer 342 and the electrolyte layer 343 stacked in the −Z-axis direction with respect to the adhesive substrate layer 341. In order for the conductive layer 342, disposed between the adhesive substrate layer 341 and the electrolyte layer 343, to contact the second contact element 262, exposure to the outside of the portion surrounded by the electrolyte layer 343 is required, and the length of the conductive layer 342 has to be designed to be longer (e.g., greater) than the length of the electrolyte layer 343, so that a portion may contact the second contact element 262.

According to an embodiment, in the second extension portion 340b of the conductive adhesive sheet 340, the length of the conductive layer 342 may be longer (e.g., greater) than the length of the adhesive substrate layer 341 and the electrolyte layer 343. In the second extension portion 340b of the conductive adhesive sheet 340, the electrolyte layer 343 is adhered (e.g., attached or bonded) to the protective cover 320 through the conductive structure 330, and the conductive layer 342 and the adhesive substrate layer 341 extending further than the electrolyte layer 343 may form a bent section. In the bent section, after bending, the adhesive substrate layer 341 is disposed to face (e.g., positioned against or to oppose) and adhere (e.g., attach or bond) another layer after being bent, and a portion of the conductive layer 342 formed to surround the adhesive substrate layer 341 may be exposed to the outside and may contact the second contact element 262.

According to an embodiment, when a voltage is applied so that the second contact element 262 has a (+) pole through the circuit board 240, the conductive layer 342 electrically connected to the second contact element 262 may form a layer having a (+) pole.

According to an embodiment, one end of the first extension portion 330b of the conductive structure 330 may be disposed to face (e.g., oppose) the first contact element 261 disposed on the circuit board 240. When a voltage is applied through the circuit board 240, the conductive structure 330 and the first contact element 261 may be substantially in contact with each other for electrical connection between the conductive structure 330 and the first contact element 261.

According to an embodiment, the first extension portion 330b of the conductive structure 330 may have one side (e.g., surface) extending inward of the circuit board 240 while being adhered (e.g., attached) to the protective cover 320, and the other side (e.g., surface) exposed to the outside, and contacting the first contact element 261.

According to an embodiment, when a voltage is applied so that the first contact element 261 has a (−) pole through the circuit board 240, the conductive structure 330 electrically connected to the first contact element 261 may form a layer having a (−) pole.

FIG. 12 is a view illustrating a state in which a voltage is applied in the cross-sectional view of the electronic device of FIG. 10 according to an embodiment of the disclosure.

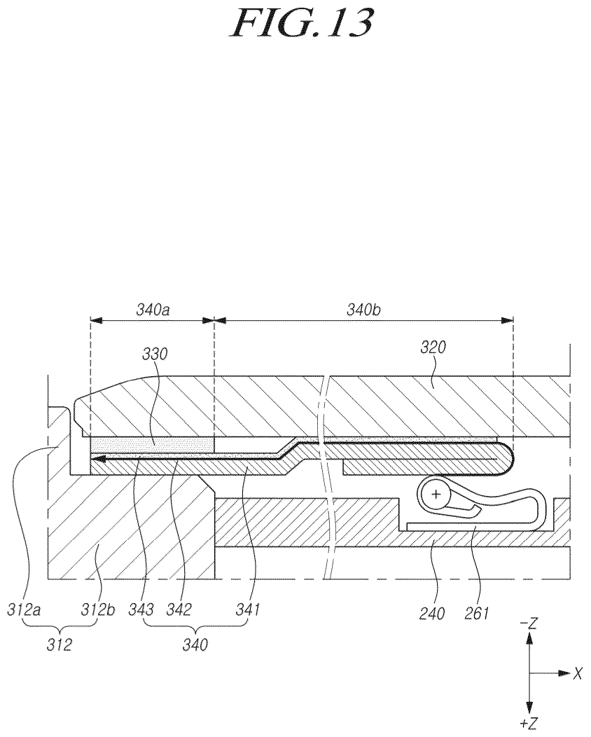

FIG. 13 is a view illustrating a state in which a voltage is applied in the cross-sectional view of the electronic device of FIG. 11 according to an embodiment of the disclosure.

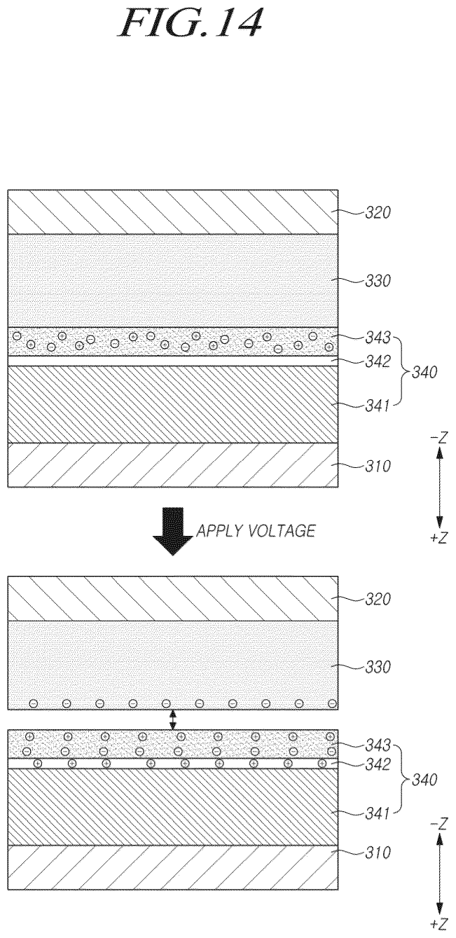

FIG. 14 is a view illustrating separation of charges related to electrical delamination after a voltage is applied to an adhesive structure according to an embodiment of the disclosure. FIG. 14 is an enlarged cross-sectional view of a first area S1 of FIG. 12.

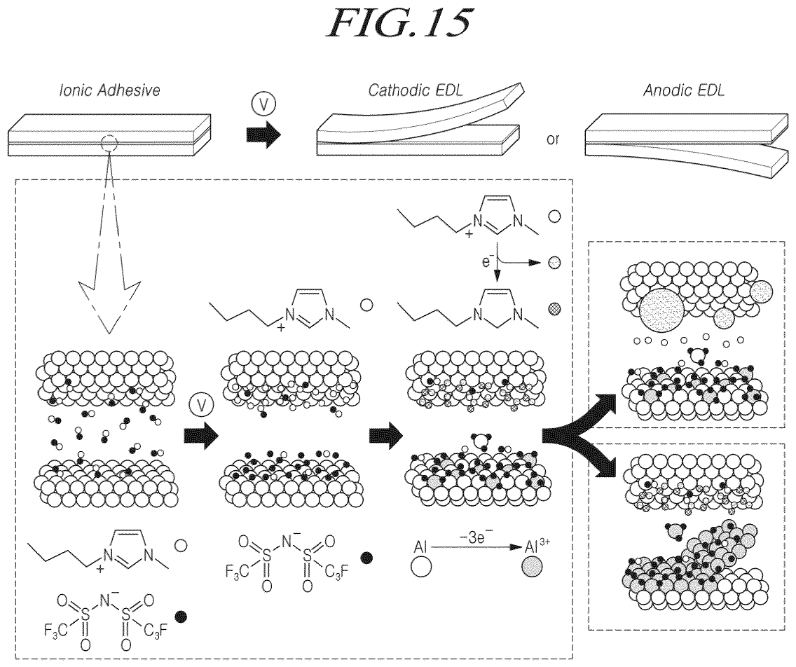

FIG. 15 is a view illustrating a configuration related to the electrical delamination of FIG. 14 according to an embodiment of the disclosure.

The configuration of the electronic device 101 of FIGS. 12 to 15 may be identical in whole or part to the configuration of the electronic device 101 of FIGS. 1 to 11.

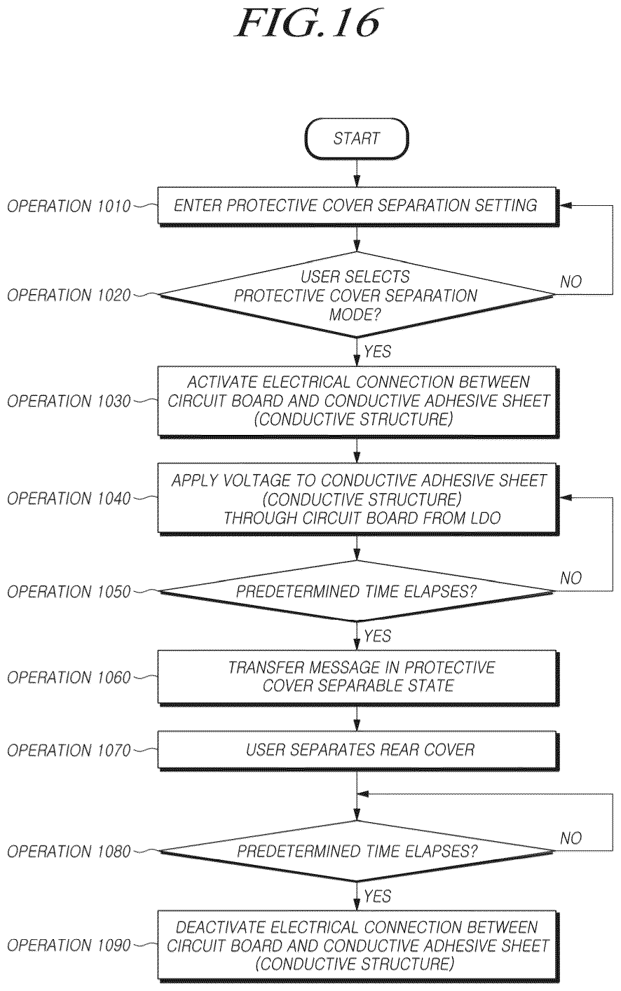

The embodiments of FIGS. 12 to 15 may be selectively combined with the embodiments of FIGS. 1 to 11 and the embodiments of FIGS. 16 to 24.

According to an embodiment, the electronic device 101 may include at least one of a housing 201, a protective cover 320, a circuit board 240, a battery 250, a conductive structure 330, and/or a conductive adhesive sheet 340.

According to an embodiment, the adhesive structure may couple the housing 310 and the protective cover 320 with a strong adhesive force. In the adhesive structure, a conductive adhesive sheet 340 including an adhesive component may be disposed between the housing 310 and the protective cover 320.

According to an embodiment, the adhesive structure may separate the protective cover 320 from the housing 310 due to the application of voltage. In order to weaken the adhesive force between the housing 310 and the protective cover, the adhesive structure may provide a structure in which a conductive adhesive sheet 340 having electrical delamination characteristics and a conductive structure 330 forming a charge transfer passage are stacked.

According to an embodiment (see FIG. 12), the first extension portion 330b of the conductive structure 330 may extend inward (e.g., in the X-axis direction) of the circuit board 240 to be electrically connected to the first contact element 261 mounted on the circuit board 240. The front side (e.g., surface) (e.g., the surface facing in the +Z axis) of the conductive structure 330 may provide one side (e.g., surface) exposed toward the circuit board 240, and a portion of the conductive structure 330 may be in physical contact with the first contact element 261. According to an embodiment, when a voltage is applied to the circuit board 240, a current may flow along the conductive structure 330 that is electrically connected. For example, if a voltage is applied so that the first contact element 261 has a (−) pole, the conductive structure 330 electrically connected to the first contact element 261 may form a layer with a (−) pole.

According to an embodiment (see FIG. 13), the second extension portion 340b of the conductive adhesive sheet 340 may extend inward (e.g., in the X-axis direction) of the circuit board 240 to be electrically connected to the second contact element 262 mounted on the circuit board 240. The conductive layer 342 of the conductive adhesive sheet 340 may be bent to provide an exposed state toward the circuit board 240, and a portion of the conductive layer 342 may be in physical contact with the second contact element 262. According to an embodiment, when a voltage is applied to the circuit board 240, a current may flow along the conductive layer 342 (that is electrically connected). For example, if a voltage is applied so that the second contact element 262 has a (+) pole, the conductive layer 342 electrically connected to the second contact element 262 may form a layer with a (+) pole.

Although FIGS. 12 and 13 disclose that the conductive structure 330 is formed to have a (−) pole, and the conductive layer 342 of the conductive adhesive sheet 340 is formed to have a (+) pole, the disclosure is not limited thereto, and various design changes may be made so that the conductive structure 330 is formed to have a (+) pole, and the conductive layer 342 of the conductive adhesive sheet 340 is formed to have a (−) pole depending on voltage conditions.

According to an embodiment (see FIG. 14), as a voltage is applied to the circuit board 240, the conductive structure 330 may be formed so that a near-edge portion toward the electrolyte layer 343 has a (+) pole, and the conductive layer 342 of the conductive adhesive sheet 340 may be formed so that a near-edge portion toward the electrolyte layer 343 has a (−) pole. Thereafter, the (−) and (+) charges mixed in the electrolyte layer 343 of the conductive adhesive sheet 340 may move to an area with opposite polarity. For example, after a certain period of time (e.g., between about 1 min and 3 min), the (−) charges (second charges) of the electrolyte layer 343 may move toward the conductive structure 330 formed to have a (+) pole, and the (+) charges (first charges) of the electrolyte layer 343 may move toward the conductive layer 342 formed to have a (−) pole. As (−) charges are arranged near the front side (e.g., surface) (e.g., the surface facing in the +Z axis) of the electrolyte layer 343, and (+) charges are arranged near the rear side (e.g., surface) (e.g., the surface facing in the −Z axis) of the electrolyte layer 343, the physical structure of the electrolyte layer 343 may be destroyed and the adhesive force of the electrolyte layer 343 may be reduced. Subsequently, the decrease in adhesive force between the conductive structure 330 and the conductive adhesive sheet 340 allows for easier separation of the protective cover 320 from the housing 310 directly by a tool such as a suction device or an operator (e.g., a user). Hereinafter, the electrical delamination characteristics of the conductive adhesive sheet 340 providing a decrease in adhesive force are described in detail.

According to an embodiment (see FIG. 15), the electrical delamination mechanism of the adhesive structure may be a method of separating the housing 310 and the protective cover 320 by weakening an adhesive force in an electrical method using an ionic liquid in the conductive adhesive sheet 340. The electrical delamination mechanism may include dissociation and diffusion of ions, and a chemical reaction at an electrode according thereto.

According to an embodiment, the electrolyte layer 343 of the conductive adhesive sheet 340 may include a mixture of an acrylic adhesive and an ionic liquid. The ionic liquid may not form a crystal due to size asymmetry between cations and anions and may stay in a liquid state. Unlike existing salts, the ionic liquid may stay in a liquid state at a temperature of about 100° C. or less.

According to an embodiment, in order for the conductive adhesive sheet 340 to provide electrical delamination characteristics, it may be necessary to arrange conductive materials adjacent to the electrolyte layer 343 so that separated charges (e.g., (+) charges and (−) charges) in the electrolyte layer 343 may easily (e.g., freely) move. For example, the conductive layer 342 and the conductive structure 330 having conductivity may contact the front side (e.g., surface) and rear side (e.g., surface), respectively, of the electrolyte layer 343 of the conductive adhesive sheet 340.

In describing an electrical delamination process of the conductive adhesive sheet 340, when a voltage is applied to the circuit board 240, a (+) voltage is applied to the conductive layer 342 (e.g., forming a layer with a (+) pole), and a (−) voltage is applied to the conductive structure 330 (e.g., forming a layer with a (−) pole), which are disposed on two opposite sides (e.g., surfaces) of the electrolyte layer 343, thereby causing dissociation and diffusion in the ionic liquid of the electrolyte layer 343. For example, the ionic liquid of the electrolyte layer 343 is composed of (+) ions and (−) ions, and if voltage is applied, the ionic liquid may be dissociated into cations and anions. Thereafter, the dissociated ions (e.g., (−) charges, and (+) charges) may move under the influence of an electric field. Anions (e.g., (−) charges) may diffuse to the (+) pole, and cations (e.g., (+) charges) may diffuse to the (−) pole.

Thereafter, a (−) pole delamination mechanism and/or a (+) pole delamination mechanism may occur. One of the (−) pole delamination mechanism and/or (+) pole delamination mechanism may be determined to be predominant depending on the chemical properties of the adhesive, the adherend, and the conditions of release. According to an embodiment of the disclosure, the (−) pole delamination mechanism occurs predominantly, and accordingly, separation of the protective cover 320 from the housing 310 may occur.

According to an embodiment, when the (−) pole delamination mechanism is described, a reduction reaction of the (+) ions may occur due to a contact between the conductive structure 330 having the (−) pole and the (+) ions in the ionic liquid of the electrolyte layer 343. As (+) ions in the electrolyte layer 343 collected toward the (−) pole of the conductive structure 330 are reduced by obtaining electrons at the (−) pole, a chemical reaction in which the adhesive force (e.g., adhesion function in the electrolyte layer 343) decreases may occur. For example, the reduced (+) ions attack the carbonyl group (C═O) that makes up the backbone structure of the acrylic adhesive, deforming or decomposing the structure of the adhesive. In the chemical reaction, hydrogen gas is generated as a by-product, and the generation of the hydrogen gas may further destabilize the adhesive structure. Accordingly, the chemical reactions may reduce the adhesive force of the acrylic adhesive at the (−) pole interface, and the weakened adhesive force may facilitate separation between the conductive structure 330 and the conductive adhesive sheet 340.

According to an embodiment, when the (+) pole delamination mechanism is described, an oxidation reaction of the (+) pole may occur due to a contact between the conductive layer 342 with (+) pole and the (−) ions in the ionic liquid of the electrolyte layer 343. (−) ions in the electrolyte layer 343 collected toward the (+) pole of the conductive layer 342 may cause an oxidation reaction at the (+) pole, and the metal (e.g., the conductive layer 342) used at the (+) pole may be oxidized in the reaction. Thereafter, as a result of the oxidation reaction, an oxide layer is formed at the (+) pole interface, and the oxide layer is formed on the side (e.g., surface) of the metal (e.g., the conductive layer 342) to weaken the adhesive force between the adhesive and the metal (e.g., the conductive layer 342). Accordingly, the adhesive force of the acrylic adhesive on the side (e.g., surface) of the metal (e.g., the conductive layer 342) is reduced due to the generation of the oxide layer, and the weakened adhesive force may facilitate separation between the conductive layer 342 and the electrolyte layer 343 in the conductive adhesive sheet 340.

FIG. 16 is a flowchart illustrating a separation operation between a housing and a protective cover of an electronic device according to an embodiment of the disclosure.

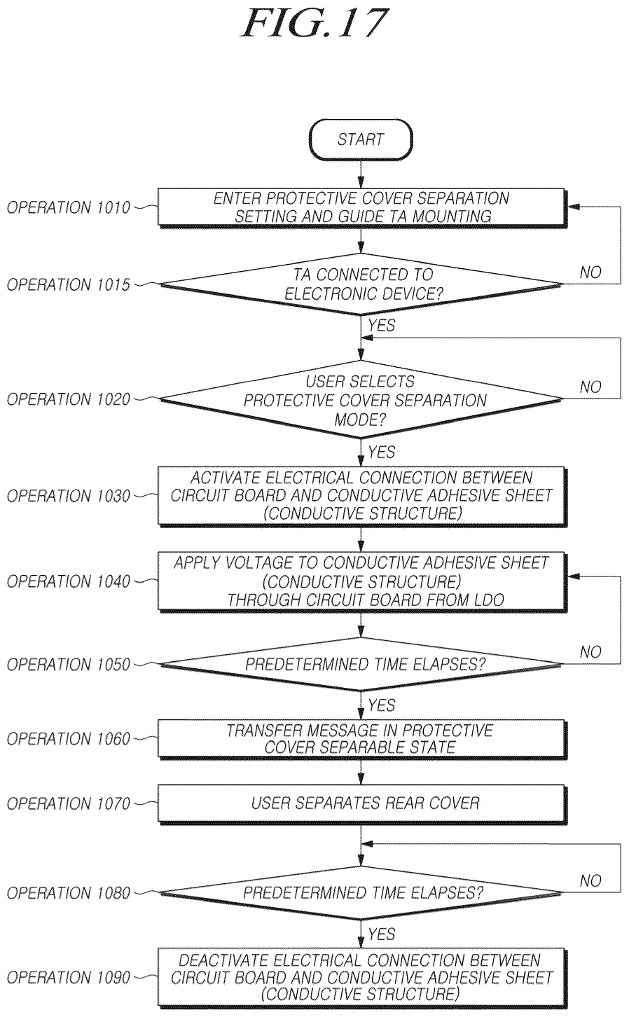

FIG. 17 is a flowchart illustrating a separation operation between a housing and a protective cover of an electronic device according to an embodiment of the disclosure.

The configuration of the electronic device 101 of FIGS. 16 and 17 may be identical in whole or part to the configuration of the electronic device 101 of FIGS. 1 to 15.

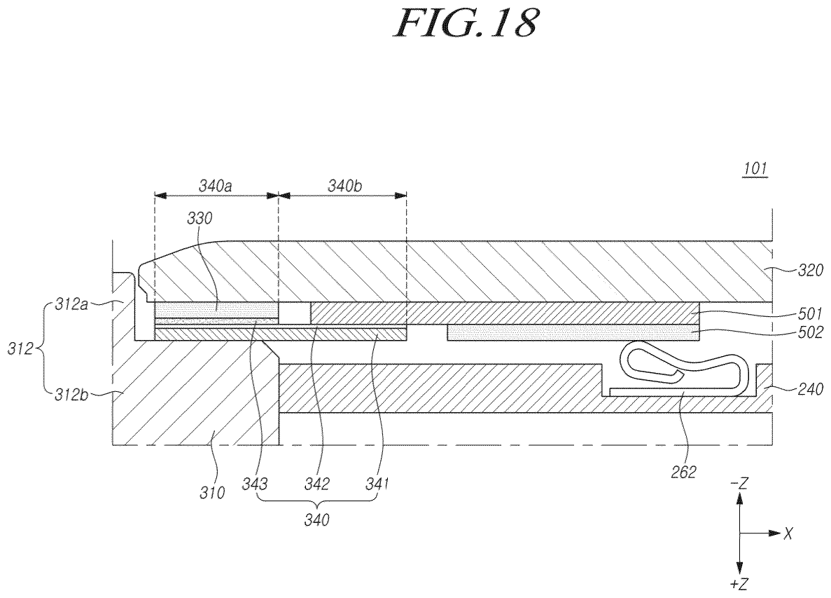

The embodiments of FIGS. 16 and 17 may be selectively combined with the embodiments of FIGS. 1 to 15 and the embodiments of FIGS. 18 to 24.

According to an embodiment, an electronic device (101 of FIGS. 1 to 14) may include at least one of a housing (310 of FIGS. 7 to 14), a protective cover (320 of FIGS. 7 to 14), a circuit board (240 of FIGS. 7 to 14), a battery (250 of FIGS. 7 to 14), a conductive structure (330 of FIGS. 7 to 14), and/or a conductive adhesive sheet (340 of FIGS. 7 to 14).

FIG. 16 is a flowchart illustrating separation of a protective cover 320 by receiving a voltage from a battery 250 in an electronic device 101.

First, when the user wants to disassemble the electronic device 101 (e.g., separate the protective cover 320 from the housing 310), the user's intention may be transferred to (e.g., identified by or determined by) the electronic device 101 (e.g., the processor 120 of FIG. 1). In operation 1010, the user may enter (e.g., input) a setting mode in the electronic device 101 and perform a mode for separating the protective cover 320 from the housing 310. The setting mode may be entered through, e.g., an application and/or a button.

In operation 1020, the processor 120 of the electronic device 101 may determine whether the user has selected separation of the protective cover 320 to perform a separation mode. When determining that the processor 120 performs the separation mode by receiving a separation mode input value in the setting mode of the electronic device 101, the processor 120 may perform a subsequent operation (e.g., operation 1030). In making the determination, as the separation mode input value in the setting mode of the electronic device 101 is not received (or a non-separation mode input value is received), the separation mode is not performed, the processor 120 may perform an operation of returning to operation 1020.

In operation 1030, the processor 120 of the electronic device 101 may activate an electrical connection between the conductive adhesive sheet 340 (and/or the conductive structure 330) and the circuit board 240. For example, the processor 120 may activate an electrical connection relationship by turning on the switches respectively connected to the first contact element 261 disposed on the circuit board 240 connected to the conductive structure 330 and the second contact element 262 disposed on the circuit board 240 connected to the conductive layer 342 of the conductive adhesive sheet 340.

In operation 1040, the processor 120 of the electronic device 101 may apply a voltage from a low dropout regulator (LDO) to the conductive adhesive sheet 340 (and/or a conductive structure 330) through the circuit board 240. For example, the LDO connected to the battery 250 may convert the voltage of the battery 250 into a stable output voltage so that the circuit of the circuit board 240 operates stably. If a voltage (e.g., 9V) is applied to the circuit board 240 through the LDO connected to the battery 250, the first contact element 261 may make the conductive structure 330 have a (−) pole through the first extension portion 330b of the conductive structure 330. If a voltage is applied to the circuit board 240 through the LDO connected to the battery 250, the second contact element 262 may make the conductive layer 342 have a (+) pole through the second extension portion 340b of the conductive adhesive sheet 340.

In operation 1050, if a predetermined time elapses while the voltage is applied, the (−) charges and (+) charges mixed in the electrolyte layer 343 may move to areas having opposite polarities. For example, between about one to two minutes, the (−) charges of the electrolyte layer 343 may move toward the conductive structure 330 forming the (+) pole, and the (+) charges of the electrolyte layer 343 may move toward the conductive layer 342 of the conductive adhesive sheet 340 forming the (−) pole. The movement of the charges may reduce the adhesive force of the electrolyte layer 343.

The processor 120 of the electronic device 101 may perform a subsequent operation (e.g., operation 1060) when a predetermined time (e.g., four minutes) elapses while the voltage is applied. The processor 120 may maintain operation 1050 before a predetermined time elapses while the voltage is applied.

In operation 1060, the processor 120 of the electronic device 101 may determine whether the protective cover 320 is separable from the housing 310, and transfer, to the user, whether the protective cover 320 is separated based on the determination. For example, the processor 120 may determine the degree of reduction in adhesive force between the conductive adhesive sheet 340 and the conductive structure 330 and transfer, to the user, whether the protective cover may be separated. For example, the processor 120 may transfer, to the user, whether the protective cover 320 may be separated after a preset (e.g., predetermined) time (e.g., four minutes or more) elapses after the voltage is applied to the circuit board 240. The method of transferring whether it is separable to the user may be transferred (e.g., provided) in various ways that the user may identify. For example, a message such as voice or text may be transferred (e.g., provided) on the display of the electronic device (or a wearable electronic device).

In operation 1070, the user (or operator) may directly separate the protective cover 320 from the housing 310 after receiving the protective cover 320 being in a state of being separable from the electronic device 101. The protective cover 320 may be separated from the housing 310 by pulling the protective cover 320 using a hand or a suction device, depending on the degree of reduction in the adhesive force between the housing 310 and the protective cover 320 (e.g., the adhesive force between the conductive adhesive sheet 340 and the conductive structure 330).

In operation 1080, the processor 120 of the electronic device 101 may perform a next process or maintain the current process according to whether a predetermined time elapses after the protective cover 320 is separated. For example, if a predetermined period of time (e.g., 20 min) elapses after the protective cover 320 is separated, operation 1090 may be performed. Operation 1080 may be maintained before a predetermined time elapses while the voltage is applied.

In operation 1090, when the processor 120 of the electronic device 101 determines that a preset time (e.g., 20 min) for operation 1080 has elapses, it may deactivate the electrical connection between the conductive adhesive sheet 340 (and/or the conductive structure 330) and the circuit board 240. For example, the processor 120 may activate an electrical connection relationship by turning off the switches respectively connected to the first contact element 261 disposed on the circuit board 240 connected to the conductive structure 330 and the second contact element 262 disposed on the circuit board 240 connected to the conductive layer 342 of the conductive adhesive sheet 340.

FIG. 17 is a flowchart illustrating separation of a protective cover 320 by receiving a voltage from an external power source. The configuration of operations 1020 to 1090 of the flowchart of FIG. 16 may be applied to the flowchart of FIG. 17. Hereinafter, operations before operation 1020 different from the flowchart of FIG. 16 are described.

Referring to FIG. 17, if the user wants to disassemble the electronic device 101 (e.g., separate the protective cover 320 from the housing 310), the user's intention (e.g., user input) may be transferred to (e.g., identified by or determined by) the electronic device 101 (e.g., the processor 120 of FIG. 1). In operation 1011, if the user enters the setting mode in the electronic device 101 and performs the mode for separating the protective cover 320 from the housing 310, the processor 120 of the electronic device 101 may guide connection between the electronic device 101 and a terminal adapter (e.g., an external power cable). The setting mode may be entered through, e.g., an application and/or a button. The guide method may be transferred (e.g., provided) to the user through the screen of the electronic device 101 in the form of a message.

In operation 1015, the processor 120 of the electronic device 101 may identify whether the electronic device 101 and the terminal adapter are electrically connected and then perform a subsequent operation. If the processor 120 determines that external power is connected to the electronic device 101, the processor may perform operation 1020. When the processor 120 determines that external power is not connected to the electronic device 101, it may return to and perform operation 1011.

Thereafter, the above-disclosed contents (e.g., processes or determinations) may be applied to operations 1020 to 1090.

FIG. 18 is a cross-sectional view of a portion the electronic device of FIG. 8, taken along B-B′ according to an embodiment of the disclosure.

The configuration of the electronic device 101 of FIG. 18 may be identical in whole or part to the configuration of the electronic device 101 of FIGS. 1 to 17.

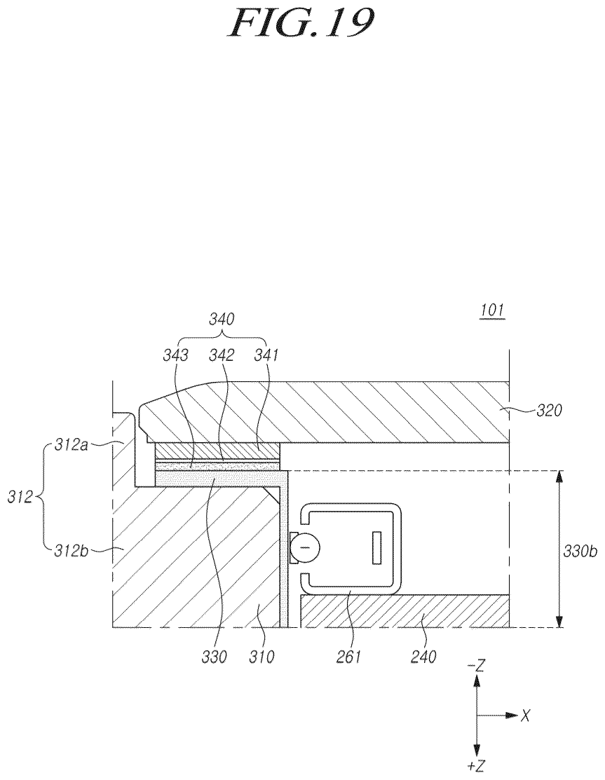

The embodiments of FIG. 18 may be selectively combined with the embodiments of FIGS. 1 to 17 and the embodiments of FIGS. 19 to 24.

FIG. 18 illustrates an electrical connection relationship between the conductive adhesive sheet 340 and the second contact element 262, and the configuration of FIG. 10 may be applied to the electrical connection relationship between the conductive structure 330 and the first contact element 261.

According to an embodiment, the electronic device 101 may include at least one of a housing 310, a protective cover 320, a circuit board 240, a conductive structure 330, and/or a conductive adhesive sheet 340.

According to an embodiment, the adhesive structure may be a structure in which the conductive adhesive sheet 340, the conductive structure 330, and the protective cover 320 are sequentially stacked on the second side wall portion 312b of the housing 310. The first side wall portion 312a of the housing 310 may be formed to surround the lateral sides (e.g., surfaces) of the conductive adhesive sheet 340, the conductive structure 330, and the protective cover 320.

According to an embodiment, the conductive adhesive sheet 340 may include an adhesive substrate layer 341, a conductive layer 342, and an electrolyte layer 343. The adhesive substrate layer 340 and the conductive layer 342 of the conductive adhesive sheet 340 may each include an extension portion (e.g., the second extension portion 340b) protruding toward the circuit board 240 to be connected to the second contact element 262.

According to an embodiment, in the second extension portion 340b of the conductive adhesive sheet 340, the conductive layer 342 may be exposed toward the protective cover 320 in a state of being disposed on the adhesive substrate layer 341. For electrical connection between the conductive layer 342 and the second contact element 262 disposed on the circuit board 240, a plurality of conductive materials may be positioned between the conductive layer 342 and the second contact element 262. The plurality of conductive materials may serve as a bridge between the conductive layer 342 and the second contact element 262. The plurality of conductive materials contact the conductive layer 342 (that is exposed) and may extend toward the second contact element 262.

According to an embodiment, the plurality of conductive materials may include a first conductive adhesive portion 501 and a second conductive adhesive portion 502. The first conductive adhesive portion 501 may be a conductive double-sided tape having double-sided adhesive properties. One side (e.g., surface) (e.g., the surface facing in the −Z axis) of the first conductive adhesive portion 501 may adhere to the protective cover 320, and the other side (e.g., surface) (e.g., the surface facing in the +Z axis) may adhere to the conductive layer 342 and the second conductive adhesive portion 502. One side (e.g., surface) of the second conductive adhesive portion 502 may be a conductive single-sided tape having one side (e.g., surface) with adhesive properties. One side (e.g., surface) (e.g., the surface facing in the −Z axis) of the second conductive adhesive portion 502 may adhere to the first conductive adhesive portion 501, and the other side (e.g., surface) (e.g., the surface facing in the +Z axis) may contact the second contact element 262.

According to an embodiment, one side of the conductive layer 342 of the conductive adhesive sheet 340 may be connected to the electrolyte layer 343 and the other side thereof may be connected to the first conductive adhesive portion 501. One side of the first conductive adhesive portion 501 may be positioned on one side (e.g., surface) (e.g., the surface facing in the −Z axis) of the conductive layer 342. According to an embodiment, in the first conductive adhesive portion 501 disposed on the protective cover 320 and extending inward of the circuit board 240, an overlapping area of the second contact element 262 may be stacked with the second conductive adhesive portion 502. The second conductive adhesive portion 502 is disposed in parallel with the conductive layer 342 and may face the second contact element 262.

According to an embodiment, the adhesive substrate layer 341, the conductive layer 342, the first conductive adhesive portion 501, and the second conductive adhesive portion 502 have a plate shape (e.g., rigid or straight shape), which may be different from the structure of the adhesive substrate layer 341 (that is bent) and the conductive layer 342 of FIG. 10. The thicknesses of the second conductive adhesive portion 502 and a portion (adhesive substrate layer 341, conductive layer 342) of the conductive adhesive sheet 340 disposed parallel to one side (e.g., surface) of the first conductive adhesive portion 501 may be substantially the same. The thickness of the first conductive adhesive portion 501 may be substantially the same as the sum of the thicknesses of the conductive layer 342 and the electrolyte layer 343.

According to an embodiment, if a voltage is applied to the circuit board 240, the current transmitted to the second contact element 262 may be transmitted to the conductive layer 342 through the second conductive adhesive portion 502 and the first conductive adhesive portion 501. For example, the conductive layer 342 may have a (+) pole.

FIG. 19 is a cross-sectional view of a portion the electronic device of FIG. 8, taken along A-A′ according to an embodiment of the disclosure.

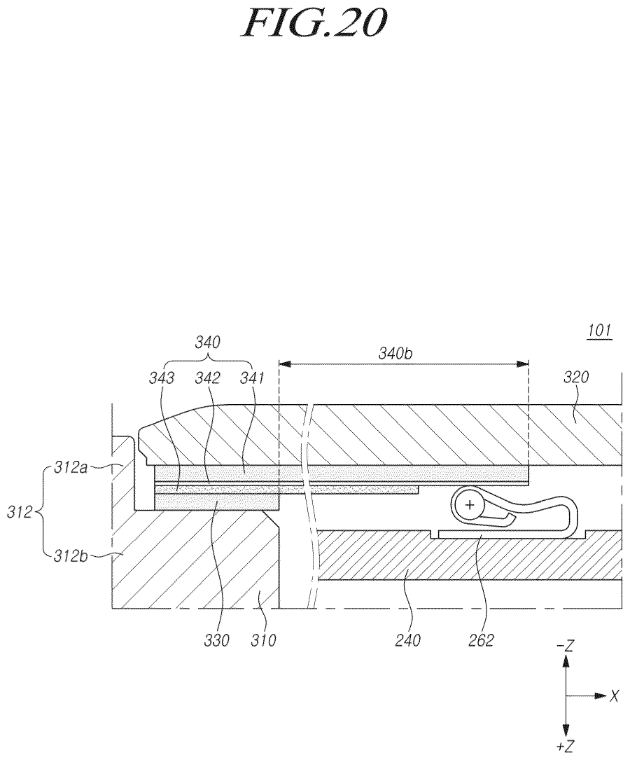

FIG. 20 is a cross-sectional view of a portion the electronic device of FIG. 8, taken along B-B′ according to an embodiment of the disclosure.

The configuration of the electronic device 101 of FIGS. 19 and 20 may be identical in whole or part to the configuration of the electronic device 101 of FIGS. 1 to 17.

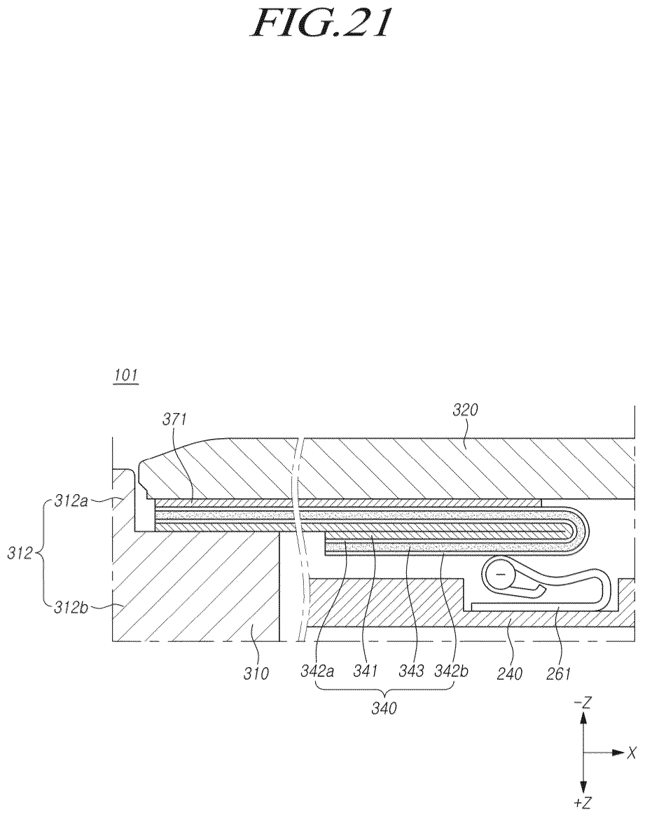

The embodiments of FIGS. 19 and 20 may be selectively combined with the embodiments of FIGS. 1 to 18 and the embodiments of FIGS. 21 to 24.

According to an embodiment, the electronic device 101 may include at least one of a housing 310, a protective cover 320, a circuit board 240, a conductive structure 330, and/or a conductive adhesive sheet 340.

FIG. 19 illustrates an electrical connection relationship between the conductive structure 330 and the first contact element 261, and FIG. 20 illustrates an electrical connection relationship between the conductive adhesive sheet 340 and the second contact element 262.

Referring to FIGS. 19 and 20, the conductive structure 330 may be disposed (e.g., coupled) along the edge of the housing 310, and the conductive adhesive sheet 340 may be disposed (e.g., adhered) along the edge of the protective cover 320, and then the conductive structure 330, and the conductive adhesive sheet 340 may be coupled (e.g., adhered).

According to an embodiment, the adhesive structure may be a structure in which the conductive structure 330, the conductive adhesive sheet 340, and the protective cover 320 are sequentially stacked on the second side wall portion 312b of the housing 310. The first side wall portion 312a of the housing 310 may be formed to surround the lateral sides (e.g., surfaces) of the conductive structure 330, the conductive adhesive sheet 340, and the protective cover 320.

Referring to FIG. 19, the conductive structure 330 may be disposed between the conductive adhesive sheet 340 and the housing 310. In the first extension portion 330b of the conductive structure 330, the conductive structure 330 may be disposed on the housing 310.

According to an embodiment, the conductive structure 330 may be disposed in a curved shape toward the support plate 311 along the second side wall portion 312b of the housing 310. A portion of the conductive structure 330 may be disposed adjacent to the circuit board 240. The conductive structure 330 may be exposed toward the circuit board 240 while being coupled to the housing 310. The conductive structure 330 may contact and electrically connect to the first contact element 261 disposed on the circuit board 240.

According to an embodiment, the conductive structure 330 extending to the circuit board 240 may be coupled to one side (e.g., surface) of the housing 310 and may differ from the structure of the conductive structure 330 extending inward of the circuit board 240 of FIG. 10. According to an embodiment, when a voltage is applied to the circuit board 240, the current transmitted to the first contact element 261 may form a path along the conductive structure 330. For example, the conductive structure 330 may have a (−) pole.

Referring to FIG. 20, the conductive adhesive sheet 340 adhered (e.g., attached) to the protective cover 320 may include an adhesive substrate layer 341, a conductive layer 342, and an electrolyte layer 343 stacked in the +Z-axis direction. The adhesive substrate layer 340 and the conductive layer 342 of the conductive adhesive sheet 340 may each include an extension portion (e.g., the second extension portion 340b) protruding toward the circuit board 240 to be connected to the contact element.

According to an embodiment, the conductive adhesive sheet 340 may be disposed between the protective cover 320 and the conductive structure 330. In the second extension portion 340b of the conductive adhesive sheet 340, the conductive layer 342 may be exposed toward the circuit board 240 in a state of being disposed on the adhesive substrate layer 341. The conductive layer 342 may contact and electrically connect to the second contact element 262 disposed on the circuit board 240.

According to an embodiment, the adhesive substrate layer 341 and the conductive layer 342 extending inward of the circuit board 240 may have a plate shape (e.g., rigid or straight shape), which may be different from the structure of the bent adhesive substrate layer 341 and the conductive layer 342 of FIG. 11. According to an embodiment, if a voltage is applied to the circuit board 240, the current transmitted to the second contact element 262 may form a path along the conductive layer 342. For example, the conductive layer 342 may have a (+) pole.

FIG. 21 is a cross-sectional view of a portion the electronic device of FIG. 8, taken along A-A′ according to an embodiment of the disclosure.

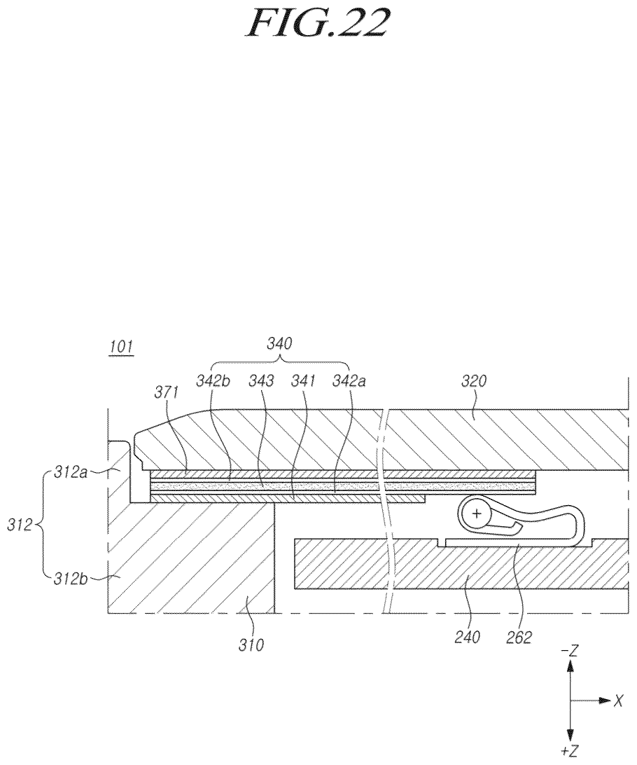

FIG. 22 is a cross-sectional view of a portion the electronic device of FIG. 8, taken along B-B′ according to an embodiment of the disclosure.

The configuration of the electronic device 101 of FIGS. 21 and 22 may be identical in whole or part to the configuration of the electronic device 101 of FIGS. 1 to 17.

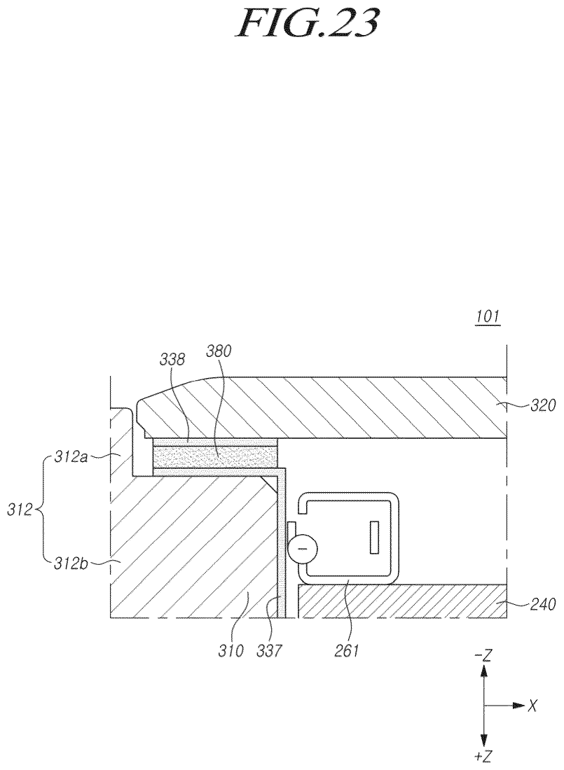

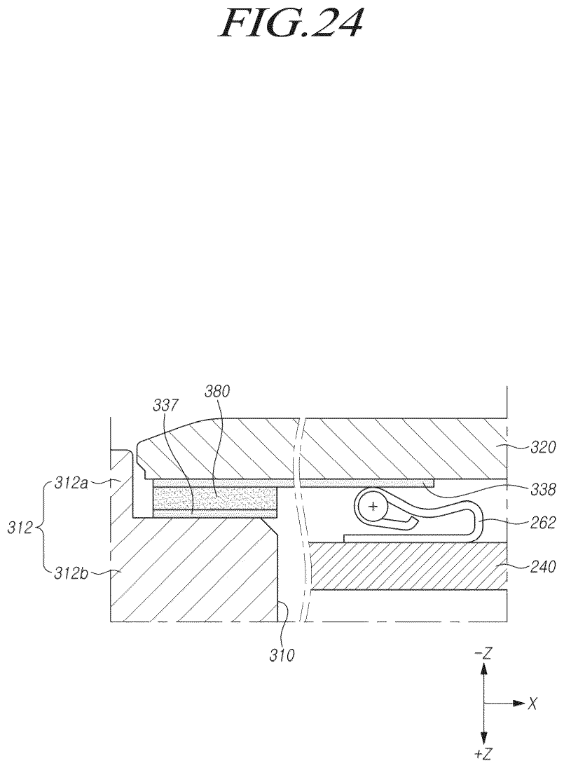

The embodiments of FIGS. 21 and 22 may be selectively combined with the embodiments of FIGS. 1 to 20 and the embodiments of FIGS. 23 to 24.

According to an embodiment, the electronic device 101 may include at least one of a housing 310, a protective cover 320, a circuit board 240, a conductive structure 330, and/or a conductive adhesive sheet 340.

FIG. 21 illustrates an electrical connection relationship between the second conductive layer 342b of the conductive adhesive sheet 340 and the first contact element 261, and FIG. 22 illustrates an electrical connection relationship between the first conductive layer 342a of the conductive adhesive sheet 340 and the second contact element 262.

Referring to FIGS. 21 and 22, the conductive adhesive sheet 340 may be disposed between the housing 310 and the protective cover 320 to couple the housing 310 and the protective cover 320.

According to an embodiment, the adhesive structure may be a structure in which the conductive adhesive sheet 340 and the protective cover 320 are sequentially stacked on the second side wall portion 312b of the housing 310. The conductive adhesive sheet 340 may include a plurality of conductive layers, and each of the conductive layers may be disposed toward the housing 310 and the protective cover 320.

According to an embodiment, the conductive adhesive sheet 340 may include an adhesive substrate layer 341, a first conductive layer 342a, an electrolyte layer 343, and a second conductive layer 342b. The adhesive substrate layer 341, the conductive layer 342, the electrolyte layer 343, and the second conductive layer 342b may have a closed loop shape corresponding to each other as a whole. The adhesive substrate layer 341, the conductive layer 342, the electrolyte layer 343, and/or the second conductive layer 342b may each include a portion extending (e.g., in the X-axis direction) toward the circuit board 240 to be connected to the contact elements 261 and 262.

According to an embodiment, the adhesive substrate layer 341 of the conductive adhesive sheet 340 may be disposed between the housing 310 (e.g., the second side wall portion 312b) and the first conductive layer 342a. The adhesive substrate layer 341 may provide a support layer function for supporting the conductive adhesive sheet 340 as a whole.

According to an embodiment, the first conductive layer 342a of the conductive adhesive sheet 340 may be disposed between the adhesive substrate layer 341 and the electrolyte layer 343. The first conductive layer 342a is a layer for moving charges constituting the electrolyte layer 343 and may provide a conducting function such as metal. For example, if a voltage is applied to the conductive adhesive sheet 340, the first conductive layer 342a has either a (−) pole or a (+) pole (e.g., the (+) pole in FIG. 22), and some of the charges of the electrolyte layer 343 may move toward the first conductive layer 342a.

According to an embodiment, the electrolyte layer 343 of the conductive adhesive sheet 340 may be disposed between the first conductive layer 342a and the second conductive layer 342b. According to an embodiment, the electrolyte layer 343 may provide a function of providing electrical delamination characteristics by including an electrolyte, and an adhesive function for adhering the conductive adhesive sheet 340 to the first conductive layer 342a and the second conductive layer 342b (or the protective cover 320), e.g., a function of a pressure-sensitive adhesive.

According to an embodiment, the electrolyte layer 343 may include a material that is dissolved in a solvent, dissociated into ions, and has electrical conductivity, and may have a state in which (+) charges and (−) charges are mixed and distributed. The electrolyte layer 343 may be in a solid electrolyte or gel electrolyte state. If a voltage is applied to the conductive adhesive sheet 340 to separate the housing 310 and the protective cover 320, the electrolyte layer 343 may separate the (+) charges and the (−) charges so that the electrolyte layer 343 and the second conductive layer 342b (or the first conductive layer 342a) may be easily separated.

According to an embodiment, the second conductive layer 342b of the conductive adhesive sheet 340 may be disposed between the electrolyte layer 343 and the protective cover 320. The second conductive layer 342b is a layer for moving charges constituting the electrolyte layer 343 and may provide a conducting function such as metal. For example, if a voltage is applied to the conductive adhesive sheet 340, the second conductive layer 342b has either a (−) pole or a (+) pole (e.g., the (−) pole in FIG. 21), and some of the charges of the electrolyte layer 343 may move toward the second conductive layer 342b.

Referring to FIG. 21, a length (X-axis direction) of the second conductive layer 342b may be longer (e.g., greater) than the lengths of other layers of the conductive adhesive sheet 340 in the extension portion of the conductive adhesive sheet 340. The conductive adhesive sheet 340 may have the first conductive layer 342a, the electrolyte layer 343, and the second conductive layer 342b stacked in the −Z-axis direction with respect to the adhesive substrate layer 341 disposed on the housing 310. In order for the second conductive layer 342b disposed between the electrolyte layer 343 and the protective cover 320 to contact the first contact element 261, exposure to the outside of the portion surrounded by the electrolyte layer 343 is required, and the length of the second conductive layer 342b is designed to be longer (e.g., greater) than the lengths of the first conductive layer 342a and the electrolyte layer 343, so that a portion may contact the first contact element 261.

According to an embodiment, in the extension portion of the conductive adhesive sheet 340, the second conductive layer 342b may be adhered to the protective cover 320 through the adhesive material 371, and the adhesive substrate layer 341, the first conductive layer 342a, the electrolyte layer 343, and the second conductive layer 342b extending toward the circuit board 240 may form a bent section. In the bent section, the second conductive layer 342b may form an outermost layer and be exposed to the outside while surrounding the adhesive substrate layer 341, the first conductive layer 342a, and the electrolyte layer 343, and may contact the first contact element 261.

Referring to FIG. 21, a length (X-axis direction) of the first conductive layer 342a may be longer (e.g., greater) than the length of the adhesive substrate layer 341 of the conductive adhesive sheet 340 in the extension portion of the conductive adhesive sheet 340. The conductive adhesive sheet 340 may have the first conductive layer 342a, the electrolyte layer 343, and the second conductive layer 342b stacked in the −Z-axis direction with respect to the adhesive substrate layer 341. In order for the first conductive layer 342a disposed between the adhesive substrate layer 340 and the electrolyte layer 343 to contact the second contact element 262, exposure to the outside of the portion surrounded by the conductive adhesive sheet 340 is required, and the first conductive layer 342a (that is exposed) may contact the second contact element 262.

FIG. 23 is a cross-sectional view of a portion the electronic device of FIG. 8, taken along A-A′ according to an embodiment of the disclosure.

FIG. 24 is a cross-sectional view of a portion the electronic device of FIG. 8, taken along B-B′ according to an embodiment of the disclosure.

The configuration of the electronic device 101 of FIGS. 23 and 24 may be identical in whole or part to the configuration of the electronic device 101 of FIGS. 1 to 17.

The embodiments of FIGS. 23 and 24 may be selectively combined with the embodiments of FIGS. 1 to 20 and the embodiments of FIGS. 23 to 24.

According to an embodiment, the electronic device 101 may include at least one of a housing 310, a protective cover 320, a circuit board 240, a conductive structure 337 and 338, and/or an electrolyte sheet 380.

FIG. 23 illustrates an example electrical connection relationship between the first conductive structure 337 and the second contact element 262, and FIG. 24 illustrates an example electrical connection relationship between the second conductive structure 338 and the first contact element 261. Referring to FIGS. 23 and 24, the first and second conductive structures 337 and 338 may be positioned between the housing 310 and the protective cover 320.

According to an embodiment, the adhesive structure may be a structure in which the first conductive structure 337, the electrolyte sheet 380, and the second conductive structure 338 are sequentially stacked on the second side wall portion 312b of the housing 310. The adhesive structure may include a plurality of conductive structures on two opposite sides of the electrolyte sheet 380, and each of the conductive structures may be disposed toward the housing 310 and the protective cover 320.

According to an embodiment, the first conductive structure 337, the electrolyte sheet 380, and the second conductive structure 338 may have a closed loop shape corresponding to each other as a whole. The first and second conductive structures 337 and 338 may include an extension portion protruding toward the circuit board 240 to be connected to the contact elements 261 and 262.

According to an embodiment, the first conductive structure 337 and the second conductive structure 338 may be disposed on the upper and lower sides (e.g., surfaces), respectively, of the electrolyte sheet 380. The first conductive structure 337 and the second conductive structure 338 are layers for moving charges constituting the electrolyte sheet 380 and may provide a conducting function such as metal. For example, if a voltage is applied to each of the first conductive structure 337 and the second conductive structure 338, the first conductive structure 337 has either a (−) pole or a (+) pole (e.g., the (−) pole in FIG. 23), and some of the charges of the electrolyte sheet 380 may move toward the first conductive structure 337. The second conductive structure 338 has either the (+) pole or the (−) pole (e.g., the (+) pole in FIG. 24), and some of the charges of the electrolyte sheet 380 may move toward the second conductive structure 338.

According to an embodiment, the electrolyte sheet 380 may include a material that is dissolved in a solvent, is dissociated into ions, and has electrical conductivity and may have a state in which (+) charges and (−) charges are mixed and distributed. If a voltage is applied to the first conductive structure 337 and the second conductive structure 338 to separate the housing 310 and the protective cover 320, the electrolyte sheet 380 may separate the (+) charges and the (−) charges so that the electrolyte layer 343 and the first conductive structure 337 (or the second conductive structure 338) may be easily separated.

Referring to FIG. 23, the first conductive structure 337 may be disposed between the electrolyte sheet 380 and the housing 310. In the extension portion (e.g., a portion extending toward the circuit board 240) of the first conductive structure 337, the first conductive structure 337 may be disposed to correspond to the curved shape of the housing 310.

According to an embodiment, the first conductive structure 337 may be disposed in a curved shape toward the support plate 311 along the second side wall portion 312b of the housing 310. A portion of the first conductive structure 337 may be disposed adjacent to the circuit board 240. The first conductive structure 337 may be exposed toward the circuit board 240 while being coupled to the housing 310. The first conductive structure 337 may contact and electrically connect to the first contact element 261 disposed on the circuit board 240.

According to an embodiment, if a voltage is applied to the circuit board 240, the current transmitted to the first contact element 261 may form a path along the first conductive structure 337. For example, the first conductive structure 337 may have a (−) pole.

Referring to FIG. 24, the length (X-axis direction) of the second conductive structure 338 may be longer (e.g., greater) than the lengths of the electrolyte sheet 380 and the first conductive structure 337 in the extension portion (e.g., the portion extending toward the circuit board 240) of the second conductive structure 338. In the adhesive structure, the electrolyte layer 343 and the second conductive structure 338 may be stacked in the −Z-axis direction with respect to the first conductive structure 337 disposed on the housing 310. In order for the second conductive structure 338 to contact the second contact element 262, exposure to the outside of a portion surrounded by the electrolyte layer 343 and the first conductive structure 337 is required, and the second conductive structure 338 (that is exposed) may contact the second contact element 262.

According to an embodiment, when a voltage is applied to the circuit board 240, the current transmitted to the second contact element 262 may form a path along the second conductive structure 338. For example, the second conductive structure 338 may have a (+) pole.

Generally, repair of an electronic device, such as a smartphone, requires a separate external heat source and a powerful suction device to remove the protective cover (e.g., the front or rear plate) from the housing. Accordingly, disassembly of a smartphone is performed at a customer center or by the manufacture company which has an external heat source and a powerful suction device, rather than by the customer, which causes inconvenience to the customer.

According to an embodiment of the disclosure, as the electronic device includes a conductive adhesive sheet with electrical delamination characteristics, the electronic device may be easily disassembled by a general user (e.g., customer).

In the electronic device according to an embodiment of the disclosure, heat required to disassemble the electronic device is supplied from the battery itself, and be provided by connecting an external power cable to the electronic device. Accordingly, the general user (e.g., customer) may easily secure necessary heat required to disassemble the electronic device.

The electronic device according to an embodiment of the disclosure may easily be disassembled by the customer without significant efforts. For example, it is possible to provide an electronic device that meets the European Union (EU) regulations (e.g., EU battery repair regulations), such as “readily removable by the end-user if it can be removed from a product using only commercially available tools, without requiring any specialized, proprietary tools, heat energy, or solvents to disassemble it.”

In the electronic device according to an embodiment of the disclosure, two contact elements may be disposed on the circuit board, and the contact elements may be electrically connected to the conductive structure coupled to the protective cover and the conductive adhesive sheet coupled to the housing, respectively. Accordingly, it is possible to easily separate the protective cover from the housing when applying a voltage to the circuit board.

Effects obtainable from the disclosure are not limited to the above-mentioned effects, and other effects not mentioned may be apparent to one of ordinary skill in the art from the following description.

An electronic device 101, according to an embodiment of the disclosure may comprise a housing 310, a protective cover 320 disposed over the housing, a circuit board 240 positioned within a housing, wherein contact elements are arranged in one area of the circuit board, a conductive structure 330 coupled along an edge of the protective cover, and having a portion electrically connected to a first contact element 261 among the contact elements, and a conductive adhesive sheet 340 coupled along an edge of the housing and having a portion electrically connected to a second contact element 262 among the contact elements. The conductive adhesive sheet 340 may be configured to adhere to the conductive structure in a shape corresponding to the conductive structure. When a voltage is applied to the conductive structure and the conductive adhesive sheet, an adhesive force between the conductive structure and the conductive adhesive sheet may be configured to decrease.

According to an embodiment, the application of the voltage may be configured to be generated through the circuit board electrically connected to an external power source or an internal power source.

According to an embodiment, a portion of the conductive structure may include a first extension portion 330b that extends inward of the circuit board towards the first contact element.

According to an embodiment, a portion of the conductive adhesive sheet may include a second extension portion 340b that extends inward of the circuit board towards the second contact element.

According to an embodiment, the first extension portion of the conductive structure and the second extension portion of the conductive adhesive sheet may be arranged parallel to each other.

According to an embodiment, a distance between the first extension portion and the circuit board and a distance between the second extension portion and the circuit board may be different.

According to an embodiment, the conductive adhesive sheet may comprise an adhesive substrate layer 341, an electrolyte layer 343 disposed facing the conductive structure, and a conductive layer 342 disposed between the adhesive substrate layer and the electrolyte layer. The conductive layer 342 may extend toward the second contact element to be electrically connected to the second contact element.

According to an embodiment, the conductive adhesive sheet may comprise an adhesive substrate layer 341, an electrolyte layer 343 disposed facing the conductive structure, and a conductive layer 342 disposed between the adhesive substrate layer and the electrolyte layer. A length of the conductive layer may be greater than a length of the adhesive substrate layer or the electrolyte layer.

According to an embodiment, the adhesive substrate layer and the conductive layer of the conductive adhesive sheet may be bent toward the circuit board, and a portion of the conductive layer exposed toward the circuit board may be configured to substantially contact the second contact element.

According to an embodiment, the conductive adhesive sheet may comprise an adhesive substrate layer 341, an electrolyte layer 343 disposed facing the conductive structure, and a conductive layer 342 disposed between the adhesive substrate layer and the electrolyte layer. When a voltage is applied to the conductive structure and the conductive adhesive sheet, ions in the electrolyte layer may be configured to move towards the conductive structure and the conductive adhesive sheet, respectively, according to their polarity.

According to an embodiment, when a voltage is applied to the conductive structure and the conductive adhesive sheet, charges of a first polarity ((+) pole) among the charges of the electrolyte layer may be configured to move toward the conductive structure, and charges of a second polarity ((−) pole) opposite to the first polarity among the charges of the electrolyte layer may be configured to move toward the conductive layer.

According to an embodiment, the first contact element and the second contact element may be arranged adjacent to the edge of the housing and are spaced apart from each other in parallel.

According to an embodiment, at least one of the conductive structure or the conductive adhesive sheet may be configured in a closed loop shape along the edge of the protective cover.

According to an embodiment, the electronic device may further comprise a battery 250 disposed in a mounting space of the housing. The application of the voltage may be configured to be generated through the circuit board electrically connected to the battery.

According to an embodiment, when a voltage is applied to the conductive structure, an electrical path may be formed through the circuit board and the first adhesive element toward the conductive structure.

According to an embodiment, when a voltage is applied to the conductive layer of the conductive adhesive sheet, an electrical path may be formed through the circuit board and the second adhesive element toward the conductive layer.

According to an embodiment, the electronic device may further comprise a display 230 disposed on the housing. The protective cover may include a rear plate of the electronic device facing opposite to the display.

According to an embodiment, the housing and the conductive structure may be formed integrally (integral).

An electronic device 101 according to an embodiment of the disclosure may comprise a housing 310, a protective cover 320 disposed over the housing, and with a conductive structure 300 coupled along an edge of the protective cover, a circuit board 240 positioned in the housing, and a conductive adhesive sheet 340 disposed along an edge of the housing and formed in a shape corresponding to the conductive structure to adhere to the conductive structure. A portion of the conductive structure and a portion of the conductive adhesive sheet may extend inward of the circuit board to be electrically connected to the circuit board. When a voltage is applied to the conductive structure and the conductive adhesive sheet, an adhesive force between the conductive structure and the conductive adhesive sheet may be configured to decrease.

According to an embodiment, the application of the voltage may be configured to be generated through the circuit board electrically connected to an external power source or an internal power source.

According to an embodiment, the electronic device may comprise a first contact element 261 and a second contact element 262 arranged in parallel on the circuit board. The first contact element may be formed to contact the portion of the conductive structure, and the second contact element may be formed to contact the portion of the conductive adhesive sheet.

According to an embodiment, the conductive adhesive sheet may comprise an adhesive substrate layer 341, an electrolyte layer 343 disposed facing the conductive structure, and a conductive layer 342 disposed between the adhesive substrate layer and the electrolyte layer. The conductive layer 342 may extend toward the second contact element to be electrically connected to the second contact element.

According to an embodiment, the conductive adhesive sheet may comprise an adhesive substrate layer 341, an electrolyte layer 343 disposed facing the conductive structure, and a conductive layer 342 disposed between the adhesive substrate layer and the electrolyte layer. A length of the conductive layer may be greater than a length of the adhesive substrate layer or the electrolyte layer.

What is claimed is:

1. An electronic device comprising:
a housing;
a cover disposed over the housing;
a circuit board positioned within a housing, wherein contact elements are arranged in one area of the circuit board;
a conductive structure coupled along an edge of the cover, the conductive structure comprising a portion electrically connected to a first contact element among the contact elements; and
a conductive adhesive sheet coupled along an edge of the housing and having a shape corresponding to the conductive structure, the conductive adhesive sheet comprising a portion electrically connected to a second contact element among the contact elements, and being configured to adhere to the conductive structure,
wherein the conductive structure and the conductive adhesive are configured such that when a voltage is applied to the conductive structure and the conductive adhesive sheet, an adhesive force between the conductive structure and the conductive adhesive sheet decreases.

2. The electronic device of claim 1, wherein the circuit board, electrically connected to an external power source or an internal power source, is configured to apply the voltage.

3. The electronic device of claim 1, wherein the portion of the conductive structure comprises a first extension portion that extends inward of the circuit board towards the first contact element, and
wherein the portion of the conductive adhesive sheet comprises a second extension portion that extends inward of the circuit board towards the second contact element.

4. The electronic device of claim 3, wherein the first extension portion of the conductive structure and the second extension portion of the conductive adhesive sheet are parallel, and
wherein a distance between the first extension portion and the circuit board is different from a distance between the second extension portion and the circuit board.

5. The electronic device of claim 1, wherein the conductive adhesive sheet comprises an adhesive substrate layer, an electrolyte layer disposed facing the conductive structure, and a conductive layer disposed between the adhesive substrate layer and the electrolyte layer, and
wherein the conductive layer extends toward the second contact element to be electrically connected to the second contact element.

6. The electronic device of claim 1, wherein the conductive adhesive sheet comprises an adhesive substrate layer, an electrolyte layer disposed facing the conductive structure, and a conductive layer disposed between the adhesive substrate layer and the electrolyte layer, and
wherein a length of the conductive layer is greater than a length of the adhesive substrate layer or the electrolyte layer.

7. The electronic device of claim 5, wherein the adhesive substrate layer and the conductive layer of the conductive adhesive sheet are bent toward the circuit board, and a portion of the conductive layer exposed toward the circuit board is configured to substantially contact the second contact element.

8. The electronic device of claim 1, wherein the conductive adhesive sheet comprises an adhesive substrate layer, an electrolyte layer disposed facing the conductive structure, and a conductive layer disposed between the adhesive substrate layer and the electrolyte layer, and
wherein when the voltage is applied to the conductive structure and the conductive adhesive sheet, ions in the electrolyte layer are configured to move towards the conductive structure and the conductive adhesive sheet, respectively, based on polarity.

9. The electronic device of claim 8, wherein the electrolyte layer is configured such that when the voltage is applied to the conductive structure and the conductive adhesive sheet, first charges of a first polarity of the electrolyte layer move toward the conductive structure, and second charges of a second polarity of the electrolyte layer move toward the conductive layer.

10. The electronic device of claim 1, wherein the first contact element and the second contact element are arranged adjacent to the edge of the housing and are spaced apart in parallel.

11. The electronic device of claim 1, wherein at least one of the conductive structure or the conductive adhesive sheet is configured in a closed loop shape along the edge of the cover.

12. The electronic device of claim 1, further comprising:
a battery disposed in a mounting space of the housing,
wherein the circuit board, electrically connected to the battery, is configured to apply the voltage.

13. The electronic device of claim 8, wherein when a voltage is applied to the conductive structure, an electrical path is formed through the circuit board and the first adhesive element toward the conductive structure, and
wherein when a voltage is applied to the conductive layer of the conductive adhesive sheet, an electrical path is formed through the circuit board and the second adhesive element toward the conductive layer.

14. The electronic device of claim 1, further comprising:
a display disposed on the housing,
wherein the cover comprises a rear plate of the electronic device opposite to the display.

15. The electronic device of claim 1, wherein the housing and the conductive structure are integral.

16. An electronic device comprising:
a housing;
a cover disposed over the housing;
a conductive structure coupled along an edge of the cover;
a circuit board positioned in the housing; and
a conductive adhesive sheet disposed along an edge of the housing and having a shape corresponding to the conductive structure, the conductive sheet being configured to adhere to the conductive structure,
wherein a portion of the conductive structure and a portion of the conductive adhesive sheet extend inward of the circuit board to be electrically connected to the circuit board, and
wherein the conductive structure and the conductive adhesive are configured such that when a voltage is applied to the conductive structure and the conductive adhesive sheet, an adhesive force between the conductive structure and the conductive adhesive sheet decreases.

17. The electronic device of claim 16, wherein the circuit board, electrically connected to an external power source or an internal power source, is configured to apply the voltage.

18. The electronic device of claim 16, further comprising:
a first contact element and a second contact element in parallel on the circuit board,
wherein the first contact element is configured to contact the portion of the conductive structure, and the second contact element is configured to contact the portion of the conductive adhesive sheet.

19. The electronic device of claim 18, wherein the conductive adhesive sheet comprises an adhesive substrate layer, an electrolyte layer disposed facing the conductive structure, and a conductive layer disposed between the adhesive substrate layer and the electrolyte layer, and
wherein the conductive layer extends toward the second contact element to be electrically connected to the second contact element.

20. The electronic device of claim 18, wherein the conductive adhesive sheet comprises an adhesive substrate layer, an electrolyte layer disposed facing the conductive structure, and a conductive layer disposed between the adhesive substrate layer and the electrolyte layer, and
wherein a length of the conductive layer is greater than a length of the adhesive substrate layer or the electrolyte layer.
